(19) United States
(12) Patent Application Publication
(10) Pub. No.: US 2024/0428351 A1
(43) Pub. Date: Dec. 26, 2024

(54) DEEP NEURAL NETWORK-BASED SYSTEM FOR DETECTION AND CLASSIFICATION OF CONSTRUCTION ELEMENTS IN CONSTRUCTION ENGINEERING DRAWINGS

(71) Applicant: Fieri Analytics Inc., Ottawa (CA)

(72) Inventors: Beinan WANG, Markham (CA); Simon SOTTILE, Ottawa (CA); Eyad ELYAN, Aberdeen (GB); Laura JAMIESON, Aberdeen (GB); Carlos MORENO-GARCIA, Aberdeen (GB)

(21) Appl. No.: 18/752,350

(22) Filed: Jun. 24, 2024

Related U.S. Application Data
(60) Provisional application No. 63/523,128, filed on Jun. 26, 2023.

(51) Int. Cl. G06Q 50/08; G06F 3/04845; G06V 10/25; G06V 10/82; G06V 30/10

(52) U.S. Cl. CPC G06Q 50/08; G06F 3/04845; G06V 10/25; G06V 10/82; G06V 30/10; G06V 2201/07

(57) ABSTRACT

A deep neural network-based system for detection and recognition of construction elements in construction engineering drawings. A first neural network performs object detection and recognition to detect and recognize ducts and fittings. A second neural network performs text detection to detect text. A third neural network performs text recognition. Pixel tracing of the construction engineering drawing is performed using the bounding box for detected text as a reference point. The recognized text is filtered to output system types and system sizes from the recognized text. Each system type and size instance is correlated to a detected duct, pipe or fitting instance to determine object coordinates, system type, item type, size and length. A list of construction elements is generated for all detected duct, pipe and fitting instances. An interactive visualization of the construction engineering drawing based on the list of construction elements and/or a costing may be provided.

### RELATED APPLICATION DATA

The present application is related to provisional U.S. patent application No. 63/523,128, filed Jun. 26, 2023, the content of which is incorporated herein by reference.

### TECHNICAL FIELD

The present disclosure relates to automatic computer-implemented construction tools, and more specifically, to a deep neural network-based system for detection and classification of construction elements in construction engineering drawings.

### BACKGROUND

The present disclosure relates to information extraction and, more specifically, to information extraction from construction engineering drawings.

Construction drawings (also known as blueprints or architectural plans) are technical drawings used to represent the design and construction of a building or other structure. Construction drawings may be used by architects, engineers, contractors and other professionals involved in the design and construction process as well as building officials and other regulatory agencies to ensure that the building or other structure is constructed in accordance with local building codes and regulations. Construction drawings include a variety of different types of drawings such as floor plans, elevations, sections, and details which illustrate the layout, design, and specifications of the building or structure. Construction drawings often also include construction engineering drawings showing electrical, mechanical, heating, ventilation, and air conditioning (HVAC), plumbing and/or fire protection systems which show the various systems and features of the building or other structure.

The various construction drawings may be generated by different professionals involved in the design and construction process. To construct the building or structure, a list of construction elements required for the construction must be prepared, costed and then sourced. The list of construction elements is conventionally generated by a person other than the professional who generated the construction drawing, often by someone with a lesser degree of knowledge than the professional who generated the construction drawing. This is an error prone and time-consuming process which is typically performed manually. Although attempts to automate this process have been made, automation has been difficult as a result of the complexity of construction drawings and the specialized knowledge required to properly interpret construction drawings. There is a need for improved systems for interpreting construction drawings, and in particular, construction engineering drawings.

Optical character recognition (OCR) is a known solution for automated document processing, however the quality and accuracy of OCR declines with the complexity of the document being processed. With respect to construction engineering drawings, OCR struggles to recognize and understand the meaning of individual text elements. Conventional OCR solutions can recognize text elements but do not understand the meaning of the text.

Artificial intelligence (AI) has been applied to OCR for complex technical document analysis, however, existing solutions have failed to be successfully applied to construction engineering drawings. One challenge of performing AI-assisted OCR on construction engineering drawings is that the AI model must understand how to separate the different parts of the drawings. Other challenges include the presence of overlapping elements, the presence of incomplete or damaged drawings, inconsistent text labelling semantics, the presence of symbols which may be incorrectly recognized as text, the proximity of text to lines and other non-text matter such as symbols. There are other challenges with performing AI-assisted OCR on construction engineering drawings such as missing text labels, implicitly defined dimensions, and the need to interpret non-text matter such as symbols.

In general, generic OCR solutions cannot reliably understand text in construction engineering drawings that is surrounded by graphical elements like lines and symbols. Although AI-assisted OCR solutions have been attempted, challenges in interpreting construction engineering drawings remain such as recognizing and interpreting non-text matter. As a result, there remains a need for improved AI-based systems for interpreting construction engineering drawings.

### SUMMARY

The present disclosure provides a deep neural network-based system for detection and classification of construction elements in construction engineering drawings, and related methods and devices. The system of the present disclosure is trained to detect and recognize both text and symbols in construction engineering drawings as well as interpret lines in construction engineering drawings to recognize ducts and pipes. The system comprises a network of neural networks which interact and cooperate with each other to recognize symbols, text, and lines, to interpret the recognized symbols, text, and lines as construction elements, and to generate a list of construction elements from the recognized construction elements. The neural networks of the system are trained individually or collectively to perform detection and recognition tasks. The system also provides a dynamic, interactive visualization of the interpreted drawings. The visualization may be used to review the interpreted drawings to identify and correct errors, to provide a mechanism of authorization regulatory compliance (e.g., for professional regulatory compliance and/or enterprise compliance (e.g., for corporate approval compliance), or other reasons. The visualization represents construction elements as dynamic, selectable user interface objects having changeable properties which can be dynamically changed by a user. The visualization may be used to change parameters of construction elements (e.g., type, dimensions, etc.), add construction elements and delete construction elements, with changes, additions and deletions automatically updating the corresponding data records, the list of construction elements and the visualization of the construction engineering drawing in real-time or near real-time. Within the visualization, displayed user interface objects corresponding to construction elements in the list of construction elements can be filtered by construction element type and/or system type, among other possibilities.

In an exemplary embodiment, the deep neural network-based system of the present disclosure comprises a first neural network that performs object detection and recognition to detect and recognize ducts, duct fittings, pipes and pipe fittings in a construction engineering drawing. The length of recognized ducts is determined from the size of the bounding boxes associated with the recognized ducts. An item type is also determined and output by the first neural network for recognized duct fittings and pipe fittings. A second neural network performs text detection to detect text in the construction engineering drawing. A third neural network performs text recognition upon detected texted. Pixel tracing of the construction engineering drawing is performed to detect pipes and determine pipe lengths using the bounding boxes for detected text as a reference point. The recognized text is filtered to output construction element properties associated with detected duct, duct fitting, pipe, pipe fitting and equipment instances. The properties comprise system types, sizes and equipment tags from the recognized text. Each detected construction element instance is associated with recognized properties comprising one or more of a system type, item type, size, length and equipment tag in dependence on the construction element type. A list of construction elements is generated for all detected duct, duct fitting, pipe, pipe fitting and equipment instances. An interactive visualization of the construction engineering drawing annotated based on the list of construction elements may be provided on a display of a user computing device, a costing of the list of construction elements may be provided and/or the list of construction elements may be output. Advantageously, the design and configuration of the deep neural network-based system, which includes three distinct deep neural networks along with special purposes software processing modules which process outputs from the various deep neural networks, include the pixel tracing module, is believed to provide a more accurate and/or efficient system over existing systems for interpretation drawings. In addition to increasing the accuracy and/or efficiency of the interpretation itself, the deep neural network-based system is believed to be more computationally efficient over the computer systems used in existing solutions as a result of the design and configuration of the deep neural network-based system. Advantageously, the method and system of the present disclosure also outputs data in a format which is readable used in visualization and costing applications.

Advantageously, some embodiments of the present disclosure provides a solution of interpreting construction engineering drawings that recognizes and interprets text and non-text matter (such as graphical elements like lines and symbols) automatically, without user input, while also providing an interactive visualization for changing, adding and deleting construction elements for user corrections. The method and system of the present disclosure stores recognized construction elements in a database structure that facilitates visualization on a remote user computing device as well as user corrections made from such a remote user computing device. The method and system of the present disclosure improves the accuracy and depth of interpretation of construction engineering drawings that is possible compared with known OCR solutions, thereby improving the system processing efficiency. The method and system of the present disclosure also provides an effective user experience via the interactive visualization of the analyzed drawings.

In accordance with a first embodiment of a first aspect of the present disclosure, there is provided a method performed by a deep neural network (DNN)-based system for detecting and recognizing construction elements in construction engineering drawings, comprising: receiving, by the DNN-based system, a construction engineering drawing from a user computing device via a communication network; performing, by a first neural network of the DNN-based system, object detection and recognition to detect and recognize ducts, pipe fittings and duct fittings in a construction engineering drawing, the first neural network outputting a unique object identifier (ID), construction element type and bounding box coordinates for each detected duct, duct fitting, pipe fitting and equipment symbol instance, each detected duct fitting and pipe fitting instance also being associated with an item type, each equipment symbol instance being associated with an equipment tag; performing, by a second neural network of the DNN-based system, text detection to detect text in the construction engineering drawing, the second neural network outputting bounding box coordinates for each detected text instance; performing, by a third neural network of the DNN-based system, text recognition upon each detected text instance to recognize the detected text contained therein, the third neural network outputting a recognized text string and bounding box coordinates for each detected text instance; performing pixel tracing of the construction engineering drawing to detect pipes using the bounding box for each detected text instance as a reference point, the pixel tracing outputting a unique object ID, construction element type and pipe coordinates for each detected pipe instance; filtering the recognized text in accordance with a predetermined set of rules to output a subset of construction element properties from the recognized text, wherein the predetermined set of rules applied depend on a construction element type associated with the recognized text, wherein the construction element properties comprises one or more of a system type, size and equipment tag; generating a list of construction elements for all detected construction element instances, each construction element instance being one of a duct, duct fitting, pipe, pipe fitting or equipment instance, wherein each construction element instance in the list of construction elements defines construction element properties comprising a construction element instance type and one or more a system type, an item type, size, length, and equipment tag in dependence on the construction element instance type.

In some or all examples of the first aspect, the method further comprises: encoding, by the first neural network of the DNN-based system, the construction engineering drawing for object detection and recognition; and encoding, by the second neural network of the DNN-based system, the construction engineering drawing for text detection.

In some or all examples of the first aspect, the method further comprises: performing, by the first neural network of the DNN-based system, object detection and recognition to detect and recognize equipment symbols for equipment tags; associating the detected and recognized equipment symbols with recognized text output from the third neural network of the DNN-based system, wherein the recognized text associated with the detected and recognized equipment symbols is determined to be an equipment tag; wherein the filtering applies predetermined rules for equipment tags on the recognized text associated with the detected shape or symbol to identify an equipment tag from the recognized text.

In some or all examples of the first aspect, the method further comprises: performing an action comprising one or more of: providing, on a display of the user computing device, an interactive visualization of the construction engineering drawing annotated within a visual user interface displayed on the display of the user computing device, wherein the annotated construction engineering drawing comprises an editable visual interface element for each detected construction element instance in the list of construction elements; obtaining and providing a costing of the list of construction elements to the user computing device via the communication network; or outputting the costing of the list of construction elements to the user computing device via the communication network.

In some or all examples of the first aspect, the interactive visualization provides real-time interactions between the user computing device and the DNN-based system.

In some or all examples of the first aspect, the costing of the list of construction elements is provided by within the visual user interface provided on the display of the user computing device.

In some or all examples of the first aspect, the visual user interface is configured to: obtain and provide the costing of the list of construction elements in response to corresponding user input, and output the costing of the list of construction elements to the user computing device via the communication network.

In some or all examples of the first aspect, the list of construction elements is provided by a quantity takeoff.

In some or all examples of the first aspect, the method further comprising: generating a quantity takeoff from the list of construction elements, wherein the quantity takeoff comprises the following information or counts: (i) length of duct, broken out by size (diameter and height/width), and system type; (ii) length of pipe, broken out by diameter and system type; (iii) quantity of pipe fittings by type, size (diameter and height/width), and system type; and (iv) quantity of duct fittings by type, size (diameter and height/width), and system type.

In some or all examples of the first aspect, the method further comprises: generating the annotated construction engineering drawing based on the construction engineering drawing and the list of construction elements; and sending, via the communication network, the annotated construction engineering drawing to the user computing device for display thereon, wherein the outputting is provided by the sending.

In some or all examples of the first aspect, outputting comprises communicating the list of construction elements to a cost module via an application programming interface (API), wherein the cost estimate is generated by the cost module which returns the cost estimation via the API.

In some or all examples of the first aspect, the method further comprises: generating a cost estimation comprising a cost of materials for each detected duct, pipe or fitting instance along with a total cost based on an individual cost of each duct, pipe or fitting instance based on the list of construction elements.

In some or all examples of the first aspect, the method further comprises: sending, via the communication network, the cost estimation to the user computing device for rendering and display thereon, wherein the outputting is provided by the sending.

In some or all examples of the first aspect, the interactive visualization represents each detected construction element as a dynamic, selectable visual interface element having changeable properties.

In some or all examples of the first aspect, the method further comprises: changing parameters of recognized construction elements, adding construction elements and removing construction elements in response to corresponding user input via the visual user interface provided on the display of the user computing device, wherein changes, additions and removals automatically update the list of construction elements, corresponding data records and the visualization of the construction engineering drawing in real-time.

In some or all examples of the first aspect, the construction element type associated with the recognized text is determined by: matching the bounding box coordinates of the recognized text with the bounding box coordinates or pipe coordinates of a matching detected duct, duct fitting, pipe, pipe fitting or equipment instance; and determining the construction element type associated with the matching detected duct, duct fitting, pipe, pipe fitting or equipment instance.

In some or all examples of the first aspect, the bounding box coordinates of the recognized text are determined to match the bounding box coordinates or pipe coordinates of a detected duct, duct fitting, pipe, pipe fitting or equipment instance when the coordinates are within a threshold distance from each other.

In some or all examples of the first aspect, each construction element is defined by a data record stored in a database managed by the system, each data record in the database comprising a corresponding object ID which uniquely identifies the respective construction element within the construction engineering drawing and information about the respective construction element including the construction element type, construction element properties and a location within the construction engineering drawing at which the construction element is located.

In some or all examples of the first aspect, a data record is generated and stored for each construction element detected by the DNN-based system or added by a user.

In some or all examples of the first aspect, the first neural network is a convolutional network (CNN), the second neural network is a Character-Region Awareness for Text detection (CRAFT) CNN, and the third neural network is a convolutional recurrent neural network (CRNN).

In some or all examples of the first aspect, each of the first neural network, the second neural network, and the third neural network are deep neural networks.

In some or all examples of the first aspect, the method further comprises: calculating a training error based on a difference between a system generated data entry and a user corrected data entry for the system generated data entry; and training the system by updating one or more parameters of a neural network of the system based on the training error.

In some or all examples of the first aspect, the second neural network and the third neural network are provided by a single neural network.

In some or all examples of the first aspect, wherein the second neural network and the third neural network are provided by distinct neural networks.

In some or all examples of the first aspect, wherein a format of the system size determined by the filtering module is dependent on the system type, wherein the format is one of diameter or length and width.

In some or all examples of the first aspect, the construction elements are one or a combination of pipes, pipe fittings, ducts, and duct fittings.

In accordance with another embodiment of the first aspect of the present disclosure, there is provided a method performed by a computing device for detection and classification of construction elements in construction engineering drawings, comprising: performing, by a first neural network, object detection and recognition to detect and recognize ducts and fittings in a construction engineering drawing, the first neural network outputting bounding box coordinates for each detected duct and fitting instance; performing, by a second neural network, text detection to detect text in the construction engineering drawing, the second neural network outputting bounding box coordinates for detected text; performing, by a third neural network, text recognition upon the detected text to recognize the detected text; performing pixel tracing of the construction engineering drawing using the bounding box for detected text as a reference point, the pixel tracing outputting pipe coordinates for each detected pipe instance; filtering the recognized text in accordance with a predetermined set of rules to output system types and system sizes from the recognized text; correlating each system type and size instance to a detected duct, pipe or fitting instance to generate coordinates, system type, item type, size and length; generating a list of construction elements for all detected duct, pipe and fitting instances, wherein the list of construction elements specifies coordinates, size, length, system type and optionally item type for each respective duct, pipe or fitting instance; and outputting the list of construction elements.

In accordance with a second aspect of the present disclosure, there is provided a deep neural network (DNN)-based system for detecting and recognizing construction elements in construction engineering drawings, wherein the construction elements one or a combination of heating, ventilation, and air conditioning (HVAC) elements, plumbing elements, and equipment, the DNN-based system comprising: one or more processors; one or more memories; and a communication subsystem; wherein the one or more memories have tangibly stored thereon executable instructions for execution by the one or more processors, wherein the executable instructions, in response to execution by the one or more processors, cause the computing device to: receive a construction engineering drawing from a user computing device via a communication network via the communication subsystem; perform, by a first neural network, object detection and recognition to detect and recognize ducts, pipe fittings and duct fittings in a construction engineering drawing, the first neural network outputting a unique object identifier (ID), construction element type and bounding box coordinates for each detected duct, duct fitting, pipe fitting and equipment symbol instance, each detected duct fitting and pipe fitting instance also being associated with an item type, each equipment symbol instance being associated with an equipment tag; perform, by a second neural network, text detection to detect text in the construction engineering drawing, the second neural network outputting bounding box coordinates for each detected text instance; perform, by a third neural network, text recognition upon each detected text instance to recognize the detected text contained therein, the third neural network outputting a recognized text string and bounding box coordinates for each detected text instance; perform pixel tracing of the construction engineering drawing to detect pipes using the bounding box for each detected text instance as a reference point, the pixel tracing outputting a unique object ID, construction element type and pipe coordinates for each detected pipe instance; filter the recognized text in accordance with a predetermined set of rules to output a subset of construction element properties from the recognized text, wherein the predetermined set of rules applied depend on a construction element type associated with the recognized text, wherein the construction element properties comprises one or more of a system type, size and equipment tag; generate a list of construction elements for all detected construction element instances, each construction element instance being one of a duct, duct fitting, pipe, pipe fitting or equipment instance, wherein each construction element instance in the list of construction elements defines construction element properties comprising a construction element instance type and one or more a system type, an item type, size, length, and equipment tag in dependence on the construction element instance type; and instruct the user computing device to provide, on a display of the user computing device, an interactive visualization of the construction engineering drawing annotated within a visual user interface displayed on the display of the user computing device, wherein the annotated construction engineering drawing comprises an editable visual interface element for each detected construction element instance in the list of construction elements.

In some or all examples of the second aspect, the executable instructions, in response to execution by the one or more processors, cause the computing device to: provide a first neural network for object detection and recognition, a second first neural network for text detection, and a third neural network for text recognition;

In some or all examples of the second aspect, the neural network is a convolutional network (CNN), the second neural network is a Character-Region Awareness for Text detection (CRAFT) CNN, and the third neural network is a convolutional recurrent neural network (CRNN).

In some or all examples of the second aspect, the executable instructions, in response to execution by the one or more processors, cause the computing device to: calculate a training error based on a difference between a system generated data entry and a user corrected data entry for the system generated data entry; and train the system by updating one or more parameters of a neural network of the system based on the training error.

Other features from the examples of the first aspect may be applied to the second and other aspects of the present disclosure.

In accordance with another aspect of the present disclosure, there is provided a computing device comprising one or more processors, one or more memories, and a communication subsystem. The one or more memories have tangibly stored thereon executable instructions for execution by the one or more processors. The executable instructions, in response to execution by the one or more processors, cause the computing device to perform the methods described above and herein.

In accordance with a further aspect of the present disclosure, there is provided one or more non-transitory machine-readable mediums having tangibly stored thereon executable instructions for execution by one or more processors of a computing device, such as a deep neural network (DNN)-based system. The executable instructions, in response to execution by the one or more processors, cause the computing device or system to perform the methods described above and herein.

Other aspects and features of the present disclosure will become apparent to those of ordinary skill in the art upon review of the following description of specific implementations of the application in conjunction with the accompanying figures.

### BRIEF DESCRIPTION OF THE FIGURES

FIG. 1A is a block diagram of an example simplified computing system suitable for use in accordance with example embodiments of the present disclosure.

FIG. 1B is a schematic block of an example of a training system architecture 100 in accordance with embodiments of the present disclosure.

FIG. 2 is a schematic block diagram of a communication system suitable for practicing example embodiments of the present disclosure.

FIG. 3 is a schematic block diagram of a deep neural network-based system for detection and classification of construction elements in construction engineering drawings in accordance with an embodiment of the present disclosure.

FIG. 4 is a table of HVAC symbols recognized by a deep neural network-based system for detection and classification of construction elements in construction engineering drawings in accordance with example embodiments of the present disclosure.

FIG. 5 is a table of pipe symbols recognized by a deep neural network-based system for detection and classification of construction elements in construction engineering drawings in accordance with example embodiments of the present disclosure.

FIG. 6 is a flowchart of a method of detection and classification of construction elements in construction engineering drawings in accordance with an embodiment of the present disclosure.

FIG. 7 is an example of a main (or home) user interface screen of a user front end application for interacting with embodiments of a deep neural network-based system in accordance with the present disclosure.

FIG. 8 is an example of a project user interface screen of a user front end application for interacting with embodiments of a deep neural network-based system in accordance with the present disclosure.

FIG. 9 is the example project user interface screen of the user front end application of FIG. 8 with an Equipment Settings window displayed.

FIG. 10 is an example of a drawing user interface screen of the user front end application for interacting with embodiments of a deep neural network-based system in accordance with the present disclosure.

FIG. 11 is the example drawing user interface screen of the user front end application of FIG. 10 with a Filter menu displayed.

FIG. 12 is the example drawing user interface screen of the user front end application of FIG. 10 with an Add Duct Fitting menu displayed.

FIG. 13 is the example drawing user interface screen of the user front end application of FIG. 10 with an Add Pipe Fitting menu displayed.

FIG. 14 is the example drawing user interface screen of the user front end application of FIG. 10 with an Add Duct Length window displayed.

FIG. 15 is the example drawing user interface screen of the user front end application of FIG. 10 with an Add Pipe Length window displayed.

FIG. 16 is the example drawing user interface screen of the user front end application of FIG. 10 with an Add Equipment window displayed.

FIG. 17 is the example drawing user interface screen of the user front end application of FIG. 910 with a Takeoff Summary (or Drawing Takeoff Report) window displayed.

FIG. 18 is the example drawing user interface screen of the user front end application of FIG. 10 with a Review Element window displayed.

FIG. 19 is a flowchart illustrating an example method for training a neural network in accordance with one example embodiment of the present disclosure.

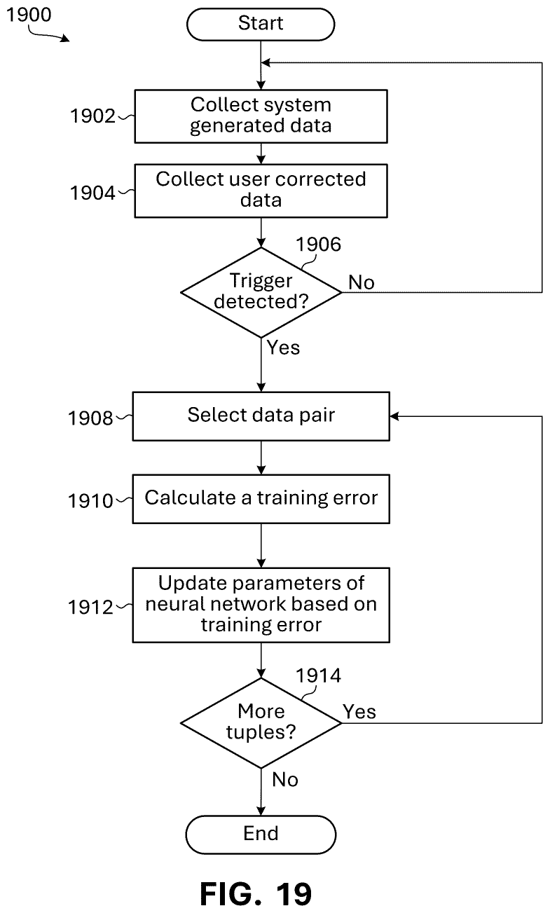

### DETAILED DESCRIPTION OF EXAMPLE EMBODIMENTS

The present disclosure is made with reference to the accompanying drawings, in which embodiments are shown. However, many different embodiments may be used, and thus the description should not be construed as limited to the embodiments set forth herein. Rather, these embodiments are provided so that this application will be thorough and complete. Wherever possible, the same reference numbers are used in the drawings and the following description to refer to the same elements, and prime notation is used to indicate similar elements, operations or steps in alternative embodiments. Separate boxes or illustrated separation of functional elements of illustrated systems and devices does not necessarily require physical separation of such functions, as communication between such elements may occur by way of messaging, function calls, shared memory space, and so on, without any such physical separation. As such, functions need not be implemented in physically or logically separated platforms, although they are illustrated separately for ease of explanation herein. Different devices may have different designs, such that although some devices implement some functions in fixed function hardware, other devices may implement such functions in a programmable processor with code obtained from a machine-readable medium. Individual functions described below may be split or subdivided into multiple functions, or multiple functions may be combined. Lastly, elements referred to in the singular may be plural and vice versa, except where indicated otherwise either explicitly or inherently by context.

For the purpose of the present disclosure, the term “real-time” means that a computing operation or process is completed within a relatively short maximum duration, typically milliseconds or microseconds, fast enough to affect the environment in which the computing operation or process occurs, such as the inputs to a computing system. The term “dynamic” refers to a result dependent on the value of a set of one or more variables, wherein the result is or may be determined in real-time in response to detection of a trigger.

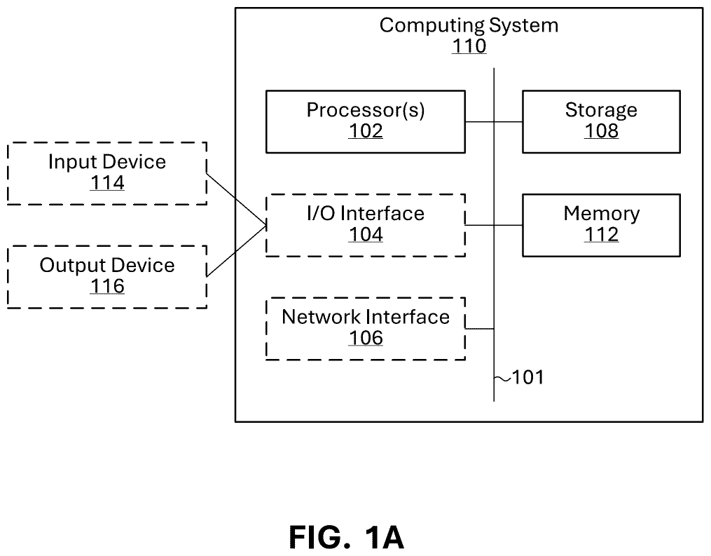

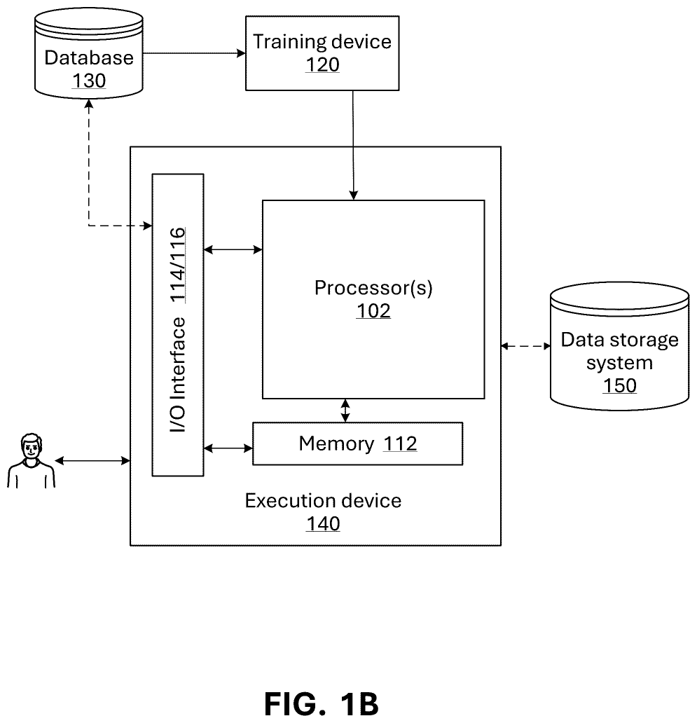

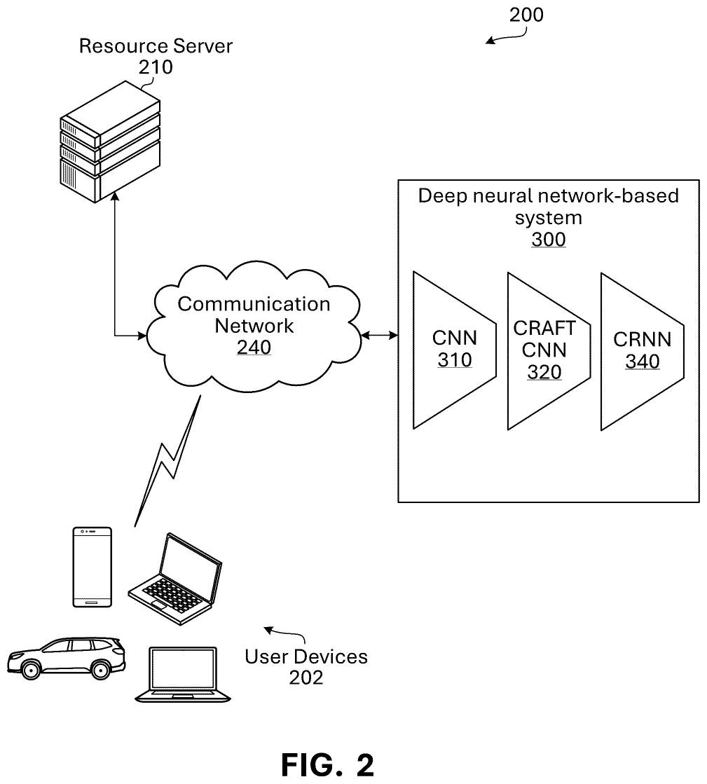

FIG. 1A illustrates a block diagram of an example simplified computing device or system 110 suitable for use in accordance with example embodiments of the present disclosure. The computing system 110 may be a user computing device (“user device” herein) 202 (FIG. 2), a deep neural network-based system 300 (FIG. 2) for detection and classification of construction elements in construction engineering drawings or a resource server 210 (FIG. 2) in accordance with examples disclosed herein. Other computing systems suitable for implementing embodiments described in the present disclosure may be used, which may include components different from those discussed below. In some examples, the computing system 110 may be implemented across more than one physical hardware unit, such as in a parallel computing, distributed computing, virtual server, or cloud computing configuration. Although FIG. 1A shows a single instance of each component, there may be multiple instances of each component in the computing system 110.

The computing system 110 may include one or more processor(s) 102, such as a central processing unit (CPU) with a hardware accelerator, a graphics processing unit (GPU), a tensor processing unit (TPU), a neural processing unit (NPU), a microprocessor, an application-specific integrated circuit (ASIC), a field-programmable gate array (FPGA), a dedicated logic circuitry, a dedicated artificial intelligence processor unit, or combinations thereof.

The computing system 110 may also include one or more optional input/output (I/O) interfaces 104, which may enable interfacing with one or more optional input devices 114 and/or optional output devices 116. In the example shown, the input device(s) 114 (e.g., a keyboard, a mouse, a microphone, a touchscreen, and/or a keypad) and output device(s) 116 (e.g., a display, a speaker and/or a printer) are shown as optional and external to the computing system 110. In other examples, one or more of the input device(s) 114 and/or the output device(s) 116 may be included as a component of the computing system 110. In other examples, there may not be any input device(s) 114 and output device(s) 116, in which case the I/O interface(s) 104 may not be needed.

The computing system 110 may include one or more optional network interfaces 106 for wired or wireless communication with a network (e.g., an intranet, the Internet, a P2P network, a WAN and/or a LAN) or other node. The network interfaces 106 may include wired links (e.g., Ethernet cable) and/or wireless links (e.g., one or more antennas) for intra-network and/or inter-network communications.

The computing system 110 may also include one or more storage units 108, which may include a mass storage unit such as a solid state drive, a hard disk drive, a magnetic disk drive and/or an optical disk drive. The computing system 110 may include one or more memories 112, which may include a volatile or non-volatile memory (e.g., a flash memory, a random access memory (RAM), and/or a read-only memory (ROM)). The non-transitory memory (ies) 112 may store instructions for execution by the processor(s) 102, such as to carry out examples described in the present disclosure. The memory (ies) 112 may include other software instructions, such as for implementing an operating system and other applications/functions. In some examples, memory 112 may include software instructions for execution by the processor 102 to train a neural network and/or to implement a trained neural network, as disclosed herein.

In some other examples, one or more datasets and/or modules may be provided by an external memory (e.g., an external drive in wired or wireless communication with the computing system 110) or may be provided by a transitory or non-transitory computer-readable medium. Examples of non-transitory computer readable media include a RAM, a ROM, an erasable programmable ROM (EPROM), an electrically erasable programmable ROM (EEPROM), a flash memory, a CD-ROM, or other portable memory storage.

There may be a bus 101 providing communication among components of the computing system 110, including the processor(s) 102, optional I/O interface(s) 104, optional network interface(s) 106, storage unit(s) 108 and/or memory (ies) 112. The bus 101 may be any suitable bus architecture including, for example, a memory bus, a peripheral bus or a video bus.

The computing system 110 may optionally invoke data, code, or the like from an external data storage system 150, to perform processing, or may store, in the memory 112, data, an instruction, or the like obtained through corresponding processing.

It should be noted that FIG. 1A is merely a schematic diagram of an example computing system 110 according to an embodiment of the present disclosure. Relationships and interactions between the device, the component, the module, and the like that are shown in FIG. 1A are not intended to be limiting to the present disclosure.

Generally, examples disclosed herein may relate to a variety of neural network applications. For ease of understanding, the following describes some concepts relevant to neural networks and some relevant terms that may be related to examples disclosed herein.

A neural network consists of neurons. A neuron is a computational unit that uses xₛ and an intercept of 1 as inputs. An output from the computational unit may be:

$$\begin{matrix}{h}_{W , b} ( x ) = f ( {W}^{T} x ) = f ( {\sum }_{s = 1}^{n} & {W}_{s} {x}_{s} + b )\end{matrix}$$

where s=1, 2, . . . n, n is a natural number greater than 1, Wₛ is a weight of xₛ, b is an offset (i.e. bias) of the neuron and f is an activation function of the neuron and used to introduce a nonlinear feature to the neural network, to convert an input of the neuron to an output. The output of the activation function may be used as an input to a neuron of a following convolutional layer in the neural network. The activation function may be a sigmoid function, for example. The neural network is formed by joining a plurality of the foregoing single neurons. In other words, an output from one neuron may be an input to another neuron. An input of each neuron may be associated with a local receiving area of a previous layer, to extract a feature of the local receiving area. The local receiving area may be an area consisting of several neurons.

A deep neural network (DNN) is also referred to as a multi-layer neural network and may be understood as a neural network that includes a first layer (generally referred to as an input layer), a plurality of hidden layers, and a final layer (generally referred to as an output layer). The “plurality” herein does not have a special metric. A layer is considered to be a fully connected layer when there is a full connection between two adjacent layers of the neural network. To be specific, for two adjacent layers (e.g., the i-th layer and the (i+1)-th layer) to be fully connected, each and every neuron in the i-th layer must be connected to each and every neuron in the (i+1)-th layer.

Processing at each layer of the DNN may be relatively straightforward. Briefly, the operation at each layer is indicated by the following linear relational expression: \vec{y}=α(W\vec{x}+\vec{b}), where \vec{x}_{\vec{x}} is an input vector, \vec{y} is an output vector, \vec{b} is an offset vector, W is a weight (also referred to as a coefficient), and α(·) is an activation function. At each layer, the operation is performed on an input vector \vec{x}, to obtain an output vector \vec{y}.

Because there is a large quantity of layers in the DNN, there is also a large quantity of weights W and offset vectors \vec{b}. Definitions of these parameters in the DNN are as follows: The weight W is used as an example. In this example, in a three-layer DNN (i.e. a DNN with three hidden layers), a linear weight from a fourth neuron at a second layer to a second neuron at a third layer is denoted as W₂₄³. The superscript 3 indicates a layer (i.e., the third layer (or layer-3) in this example) of the weight W, and the subscript indicates the output is at layer-3 index 2 (i.e., the second neuron of the third layer) and the input is at layer-2 index 4 (i.e., the fourth neuron of the second layer). Generally, a weight from a k-th neuron at an (L−1)-th layer to a j-th neuron at an L-th layer may be denoted as Wⱼₖ^{L}. It should be noted that there is no W parameter at the input layer.

In a DNN, a greater number of hidden layers may enable the DNN to better model a complex situation (e.g., a real-world situation). In theory, a DNN with more parameters is more complex, has a larger capacity (which may refer to the ability of a learned model to fit a variety of possible scenarios), and indicates that the DNN can complete a more complex learning task. Training of the DNN is a process of learning the weight matrix. A purpose of the training is to obtain a trained weight matrix, which consists of the learned weights W of all layers of the DNN.

In the process of training a DNN, a predicted value outputted by the DNN may be compared to a desired target value (e.g., a ground truth value). A weight vector (which is a vector containing the weights W for a given layer) of each layer of the DNN is updated based on a difference between the predicted value and the desired target value. For example, if the predicted value outputted by the DNN is excessively high, the weight vector for each layer may be adjusted to lower the predicted value. This comparison and adjustment may be carried out iteratively until a convergence condition is met (e.g., a predefined maximum number of iterations has been performed, or the predicted value outputted by the DNN is sufficiently converged with the desired target value). A loss function or an objective function is defined, as a way to quantitatively represent how close the predicted value is to the target value. An objective function represents a quantity to be optimized (e.g., minimized or maximized) in order to bring the predicted value as close to the target value as possible. A loss function more specifically represents the difference between the predicted value and the target value, and the goal of training the DNN is to minimize the loss function.

Backpropagation is an algorithm for training a DNN. Backpropagation is used to adjust (also referred to as update) a value of a parameter (e.g., a weight) in the DNN, so that the error (or loss) in the output becomes smaller. For example, a defined loss function is calculated, from forward propagation of an input to an output of the DNN. Backpropagation calculates a gradient of the loss function with respect to the parameters of the DNN, and a gradient algorithm (e.g., gradient descent) is used to update the parameters to reduce the loss function. Backpropagation is performed iteratively, so that the loss function is converged or minimized.

A convolutional neural network (CNN) is a DNN with a convolutional structure. The CNN includes a feature extractor consisting of a convolutional layer and a sub-sampling layer. The feature extractor may be considered as a filter. A convolution process may be considered as performing convolution on a two-dimensional (2D) input image or a convolutional feature map using a trainable filter.

The convolutional layer is a layer of neurons at which convolution processing is performed on an input in the CNN. In a convolutional layer, one neuron may be connected only to a subset of neurons (i.e., not all neurons) in neighboring layers. That is, a convolutional layer generally is not a fully connected layer. One convolutional layer usually includes several feature maps, and each feature map may be formed by some neurons arranged in a rectangle. Neurons at a same feature map share weights. The shared weights may be collectively referred to as a convolutional kernel. Typically, a convolutional kernel is a 2D matrix of weights. It should be understood that the convolutional kernel may be unrelated to a manner and position of image information extraction. A hidden principle behind convolutional layers is that statistical information of a part of an image is the same as that of another part of the image. This means that image information learned from one part of the image may also be applicable for another part of the image. A plurality of convolutional kernels may be used at the same convolutional layer to extract different image information. Generally, a larger quantity of convolutional kernels indicates that richer image information is reflected by a convolution operation.

A convolutional kernel may be initialized as a 2D matrix of random values. In a training process of the CNN, the weights of the convolutional kernel are learned. An advantage of using the convolutional kernel to share weights among neurons in the same feature map is that the connections between convolutional layers of the CNN is reduced (compared to the fully connected layer) and the risk of overfitting is lowered.

A recurrent neural network (RNN) is a type of neural network (usually a DNN) that is often used to process sequence data, where there is expected to be some relationship in the sequential order of the data (e.g., in a set of temporal data containing data over a sequence of time steps, or in set of text data where information is encoded in the order of the words in the text). For example, to predict a word in a sentence, a previous word is usually needed, because the likelihood of a predicted word is dependent on the previous word(s) in a sentence. In RNNs, computation of a current predicted output of a sequence is also related to a previous output. Conceptually, a RNN may be understood as “memorizing” previous information and applying the previous information to computation of the current predicted output. In terms of the neural network layers, the nodes between the hidden layers are connected such that an input to a given hidden layer includes an output from a preceding layer, and additionally includes an output generated by the hidden layer from a previous input. This may be referred to as parameter sharing, because parameters (e.g., layer weights) are shared across multiple inputs to the layer. Thus, the same input to the hidden layer, provided at different sequential position in the sequence data, can result in different output being generated by the hidden layer depending on previous inputs in the sequence. A RNN may be designed to process sequence data of any desired length.

Training of the RNN may be similar to the training of a conventional CNN or DNN. The error backpropagation algorithm may also be used. To account for the parameter sharing in the RNN, in a gradient descent algorithm, the output of each gradient step is calculated from the weights of a current step, and additionally from the weights of several previous steps. The learning algorithm for training the RNN may be referred to as back propagation through time (BPTT).

Gated convolution is a technique in which two different sets of convolution weights are applied to a single gated convolutional layer to generate two separate convolutional outputs. A set of gate weights, denoted as W_{g}, is used to compute a set of gate values; and a set of feature weights, denoted as W_{f}, is used to compute a set of features for the layer. The gate values are used as input to a gating function, to enable dynamic control of what information from the computed set of features is passed to the next layer.

A gated convolutional layer may be described using the following:
G=conv (W_{g}, I)
F=conv (W_{f}, I)
O=σ(G)⊙ψ(F)

where I is the set of inputs to the gated convolutional layer, G is the set of gate values, F is the set of feature values, O is the gated output of the gated convolutional layer, σ is the Sigmoid function (used as the gating function), and ψ is the activation function. It may be noted that the output values of the Sigmoid function are within [0, 1]. Thus, gated convolution enables the neural network to learn a dynamic feature selection mechanism.

A gated recurrent unit (GRU) is a mechanism used for gating in RNNs. As previously discussed, an RNN involves connections between hidden layers of the neural network. The GRU introduces mechanisms to control updating of a hidden state should be updated and to control resetting of a hidden state. These mechanisms are referred to as the update gate and the reset gate, each of which are learned weight vectors. Generally speaking, the reset gate controls how much of a previous state contributes to a current state of a hidden layer, and the update gate controls how much of the current state is copied from the previous state. GRU is a technique that may be used to enable a RNN to continue to learn from older hidden states.

A generative adversarial network (GAN) is a deep learning model, and provides another technique for training a DNN. A GAN includes at least two modules: one module is a generative model (also referred to as a generator), and the other module is a discriminative model (also referred to as a discriminator). These two models compete with each other and learn from each other, so that a better output is generated. The generator and the discriminator may both be neural networks, and may be specifically DNNs, or CNNs.

A basic principle of the GAN is now described, using the example of photo generation. The generator is a network that is learning to perform the task of producing a synthetic photo. The generator receives a random noise z as input, and generates an output, denoted by G(z). The discriminator is a network that is learning to discriminate whether a photo is a real-world photo. The discriminator receives the input x, where x represents a possible photo. An output D(x) generated by the discriminator represents the probability that x is a real-world photo. If D(x) is 1, it indicates that x is absolutely a real-world photo. If D(x) is 0, it indicates that x absolutely is not a real-world photo. In training the GAN, an objective of the generator is to generate a photo as real as possible (to avoid detection by discriminator), and an objective of the discriminator is to try to discriminate between a real-world photo and the photo generated by the generator. Thus, training constitutes a dynamic adversarial process between the generator and the discriminator. The aim of the training is for the generator to learn to generate a photo that the discriminator cannot discriminate from a real-world photo (ideally, D(G(z))=0.5). The trained generator is then used for model application, which is generation of a synthetic photo in this example.

Reference is now made to FIG. 1B, which shows an example of a training system architecture 100 in accordance with embodiments of the present disclosure. The following description shall not be construed as a limitation to any examples of this disclosure. As shown in training the system architecture 100, training data may be stored in a database 130. In the context of the present disclosure, training data may include construction engineering drawings, construction engineering symbols such as HVAC and piping symbols, and construction and engineering scales. The database 130 may contain, for example, training datasets that have been previously collected and commonly used for training models related to image tasks (e.g., image recognition). The database 130 may alternatively or additionally contain images optionally collected (e.g., with user consent) from an execution device 140, such as the computing system 110 (which may be a user device). For example, construction engineering drawings, construction engineering symbols such as HVAC and piping symbols, and construction and engineering scales captured by and stored on the execution device 140 may optionally be anonymized and uploaded to the database 130.

As will be discussed further below, training of a computing device 110 may be performed using a training device 120, using the training data maintained in the database 130. The training device 120 may use samples of the training data stored in the database 130 to train the computing system 110. Additionally or alternatively, the training device 120 perform the training using training data obtained from other sources, such as a distributed storage (or cloud storage platform).

The trained computing device 110 obtained through training by the training device 120 may be applied to different systems or devices. For example, the trained computing device 110 may be applied to a computation module 111 of an execution device 140. Although FIG. 1B illustrates an example in which the training device 120 is separate from the execution device 140, it should be understood that the present disclosure is not limited to this. In some examples, there may not be separate training device 120 and execution device 140. That is, training of the computing device 110 and application of the trained computing device 110 may be at the same device.

Reference is next made to FIG. 2 which shows in schematic block diagram form a communication system 200 suitable for practicing example embodiments of the present disclosure. The system 200 includes a plurality of computing/communication devices operated by users (“user devices”) 202, a deep neural network-based system 300 for detection and classification of construction elements in construction engineering drawings and optionally a resource server 210.

The user devices 202 communicate with the deep neural network-based system 300 and optionally the resource server 210 via a communication network 240 which comprises, or is connected to, the Internet. The deep neural network-based system 300 provides a cloud-based back-end analytical services for users in which some or all of the computational functions of detection and classification of construction elements in construction engineering drawings are performed by the system 300 with the user devices 202 acting as a thin client that performs primarily data input and output functions. The user devices 202 run a user front end application 250 for which communicates and interacts with the system 300. Examples of a user device 202 include, but are not limited to, a smart TV, a personal computer such as a desktop or laptop computer, a smartphone, a tablet, smart glasses or other head device mounted smart display, a smart speaker or other smart or IoT (Internet of Things) device such as a smart appliance or smart car, among other possibilities.

The communication network 240 enables exchange of data between the user devices 202, the deep neural network-based system 300 and the resource server 210. The communication network 240 may comprise one or a plurality of networks of one or more network types coupled via appropriate methods known in the art such as a local area network (LAN), a wireless local area network (WLAN) such as Wi-Fi™, a wireless personal area network (WPAN) such as Bluetooth™ based WPAN, a wide area network (WAN), a public-switched telephone network (PSTN), or a public-land mobile network (PLMN), also referred to as a wireless wide area network (WWAN) or a cellular network. The WLAN may include a wireless network which conforms to IEEE 802.11x standards or other communication protocol.

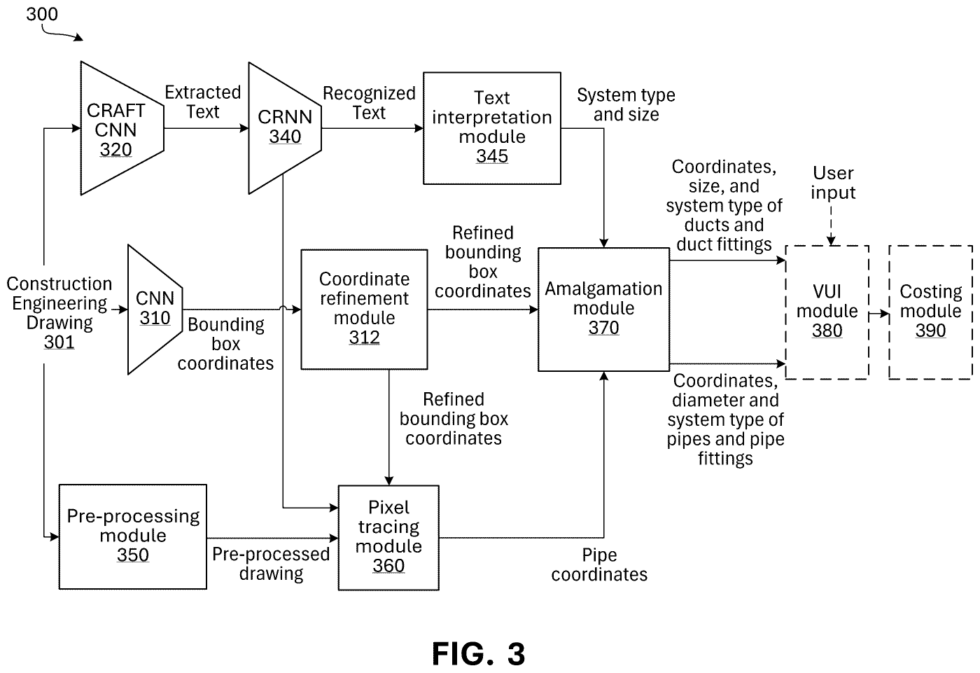

FIG. 3 is a schematic diagram of a deep neural network-based system 300 for detection and classification of construction elements in construction engineering drawings. The system 300 comprises a number of functional software modules, referred to individually by references 310, 312, 320, 340, 345, 350, 360, 370 and 380, which, in response to execution by one or more processors of a computing system 110 (FIG. 1), cooperate to perform a method 400 of the detection and classification of construction elements in construction engineering drawings in accordance with an embodiment of the present disclosure. The system 300 detects pipes, ducts and fittings (for pipes and ducts) using a shared (or common) processing pipeline, described more fully below.

As described more fully below, at least some of the software modules of the system 300 may comprise one or more neural networks (NNs). Each NN may comprise one or more subnetworks (“subnets”), which may in turn comprise one or more NNs. The NNs may be convolutional neural networks (CNNs), in particular deep CNNs, which are individually configured, by training, to perform one or more steps or actions in the method 400. The system 300 is connected to user devices 102 (FIG. 1) via the communication network 104 by one or more of a wired or wireless communication path. The system 300 may also be connected to the resource server 120 (FIG. 1) with supplemental data, such as engineering data or project data, may be located on-site or remotely from the system 300.

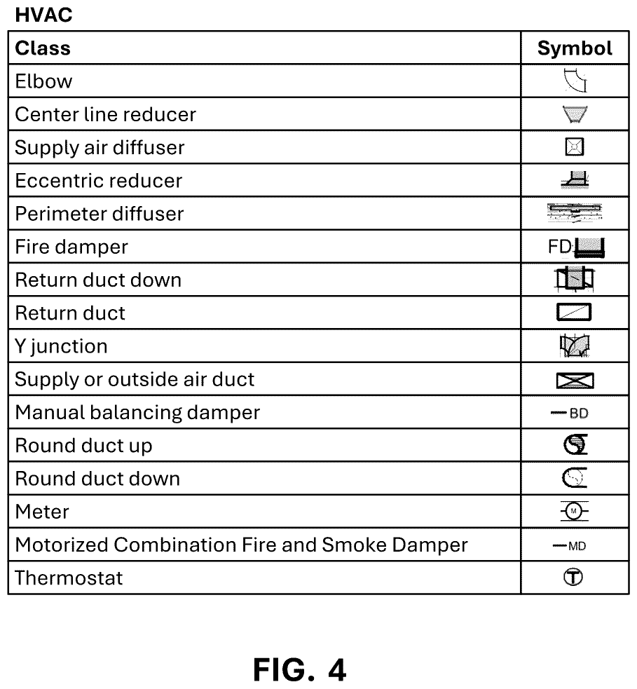

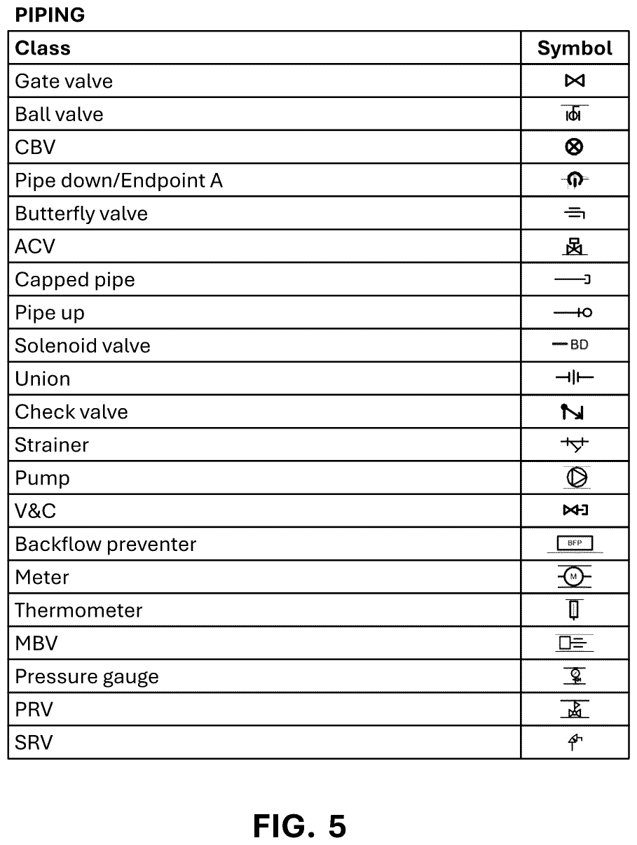

A first neural network, duct and fitting detection CNN 310 in the shown embodiment, receives a construction engineering drawing 301 from a user device 202 by a user via a user front end and encodes the construction engineering drawing 301 for object detection and recognition. The construction engineering drawing 301 may be a color digital image (also known as an RGB (red green blue) image) or black and white digital image, or may be converted from another file format (such as a Portable Document Format (PDF)) into a color or black and white digital image. The CNN 310 is trained to process the construction engineering drawing 301 and detect ducts and fittings (for ducts and pipes) using an object detection algorithm such as the “You only look once” or “YOLO” algorithm. Version 7.0 of the “YOLO” algorithm is used in at least some embodiments, which is described by Chien-Yao Wang, Alexey Bochkovskiy and Hong-Yuan Mark Liao in YOLOv7: Trainable bag-of-freebies sets new state-of-the-art for real-time object detectors, arXiv: 2207.02696, Jul. 6, 2022, the content of which is incorporated herein by reference. Implementation parameters, configurations and other data for version 7.0 of the “YOLO” algorithm is found at https://github.com/WongKinYiu/yolov7, the content of which is incorporated herein by reference. To detect fittings, the CNN 310 is trained to detect fitting symbols corresponding to pipes and ducts. FIG. 4 illustrates HVAC symbols used for duct that are recognized in accordance with example embodiments of the present disclosure. FIG. 5 illustrates pipe symbols recognized accordance with example embodiments of the present disclosure.

As noted above, the CNN 310 is trained to detect ducts, duct fittings and pipe fittings. An example of a dataset for training the CNN 310 to detect ducts is the Sloth dataset, which is comprised of mechanical drawings from all types of commercial and residential construction, found at https://sloth.readthedocs.io/en/latest/, the content of which is incorporated herein by reference. The CNN 310 is trained to detect fittings using a proprietary symbol library. Examples of symbols used in the symbol library are found in FIGS. 4 and 5. A proprietary dataset was used to train the CNN 310 to detect fittings and the trained CNN 310 was evaluated using mean average precision (mAP).

The CNN 310 detects ducts and fittings in the construction engineering drawing 301, generates a bounding box for each duct and fitting detected in the construction engineering drawing 301, and outputs a set of coordinates (x, y, h, w) of each bounding box, where x, y are pixel coordinates of top left corner of the respective bounding box, and h, w are the height and width (in pixels) of the respective bounding box. For fittings, a fitting type is also output for each bounding box. The fitting bounding boxes are used in pixel tracing for determining pipe coordinates, as described more fully below.

In least some embodiments, the CNN 310 determines a confidence level (or probability) with each possible detection and only detects an object (such as a duct or fitting) when the confidence level of the possible detection meets or exceeds a confidence threshold. Any object in the drawing 301 that was not detected by the system 300 due to having a confidence level below the confidence threshold must be added by a user. The confidence threshold may vary between object types, such as between ducts and fittings, and possibly between fitting types. The confidence threshold may be set by the operator of the system 300 or learned. The confidence thresholds are represented by various parameters/weights of the various neural networks of the system 300.

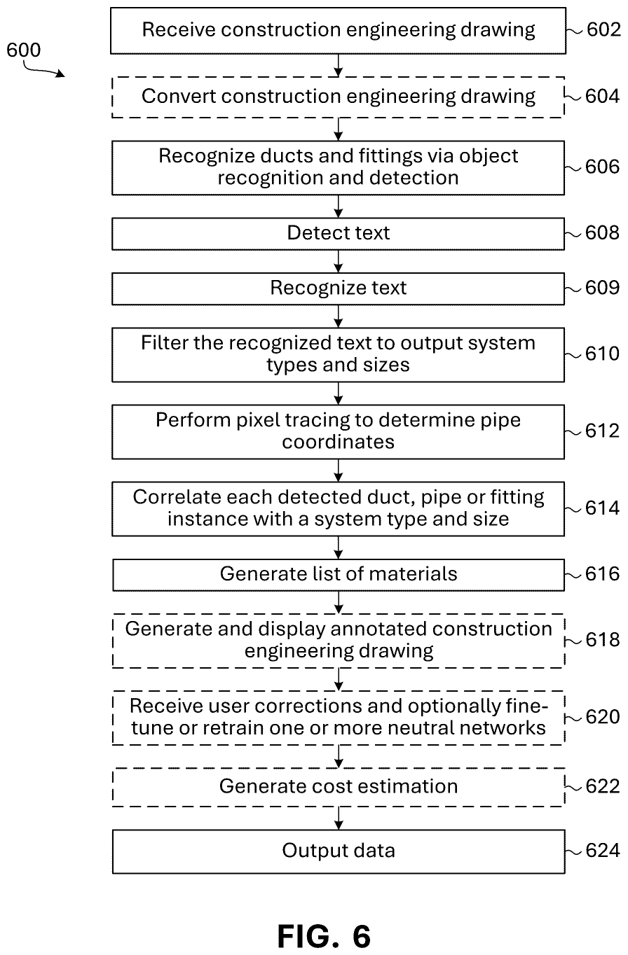

The bounding box coordinates output by the CNN 310 are sent to a coordinate refinement module 312 in which the bounding box coordinates for ducts and fittings are refined. If the construction engineering drawing 301 is a color image, it is converted into a binary black and white image consisting of black and white pixels. The conversion may be limited to the areas of the construction engineering drawing 301 that correspond to the detected bounding boxes for computational efficiency. The conversion, when performed, occurs after the CNN 310 and before the coordinate refinement module 312. Alternatively, the conversion of the entire image from color to black and white may occur previously, for example, upon the construction engineering drawing 301 being uploaded to the system 300 by a user (see step 602 of the method 600 of FIG. 6).

Because ducts are drawn as rectangles with black sides on construction engineering drawings, the initial detections by the CNN 310 provide bounding box coordinates of ducts which may include areas outside of the ducts. The outside areas mostly consist of white pixels. The coordinate refinement module 312 performs a detection refining method that eliminates the outside areas by shrinking the bounding boxes from the centers of all four sides until black pixels are encountered.

The detection refining method first locates a center point of each side of the initial bounding box. Starting from the left side, the center point is checked to see if it corresponds to a white pixel of the binarized image. In response to the center point of the left side corresponding to a white pixel, the center point is moved one pixel unit to the right. This process is repeated until the center point of the left side corresponds to a black pixel. This point becomes the new center point for the left side of the initial bounding box. The center point of the right side of the initial bounding box is then checked to see if it corresponds to a white pixel of the binarized image. In response to the center point of the right side corresponding to a white pixel, the center point is moved one pixel unit to the left. This process is repeated until the center point of the right side corresponds to a black pixel. This point becomes the new center point for the right side of the initial bounding box. The center point of the top side of the initial bounding box is then checked to see if it corresponds to a white pixel of the binarized image. In response to the center point of the top side corresponding to a white pixel, the center point is moved one pixel unit down. This process is repeated until the center point of the top side corresponds to a black pixel. This point becomes the new center point for the top side of the initial bounding box. The center point of the bottom side of the initial bounding box is then checked to see if it corresponds to a white pixel of the binarized image. In response to the center point of the bottom side corresponding to a white pixel, the center point is moved one pixel unit up. This process is repeated until the center point of the bottom side corresponds to a black pixel. This point becomes the new center point for the bottom side of the initial bounding box.

The coordinate refinement module 312 outputs refined bounding box coordinates which are more precise and contain little to no outside area. The length of the refined bounding boxes in pixels, in conjunction with the drawing scale, is used to determine the length of ducts and pipes in the construction engineering drawing 301 as described more fully below. The drawing scale may be detected using text detection and recognition or may be manually input by a user, depending on the embodiment.

The construction engineering drawing 301 received from the user device 202 is also sent to a second neural network, a Character-Region Awareness for Text detection (CRAFT) CNN 320 in the shown embodiment. The CNN 320 encodes the construction engineering drawing 301 for text detection. Implementation parameters, configurations and other data for the CNN 320 in accordance with at least some embodiments is found at https://github.com/clovaai/CRAFT-pytorch, the content of which is incorporated herein by reference. The CNN 320 is trained to detect text in the construction engineering drawing 301. The CNN 320 outputs the bounding box coordinates of the detected text. The CNN 320 may also output the detected text.

A third neural network, a convolutional recurrent neural network (CRNN) 340 in the shown embodiment, receives the bounding box coordinates of the detected text from the CNN 320. The CRNN 340 may also receive the detected text. Alternatively, the CRNN 340 receives the construction engineering drawing 301 and encodes it text recognition. An example architecture for the CRNN 340 is described by Baoguang Shi, Xiang Bai and Cong Yao in An End-to-End Trainable Neural Network for Image-based Sequence Recognition and Its Application to Scene Text Recognition, arXiv: 1507.05717, 21 Jul. 2015, the content of which is incorporated herein by reference. An example of a trained CRNN 340 is EasyOCR, information, data and code for which is found at https://github.com/JaidedAI/EasyOCR, the content of which is incorporated herein by reference. The CRNN 340 is trained to recognize and extract the detected text from the construction engineering drawing 301. The output of the CRNN 340 is the bounding box coordinates of the text and the recognized text, which is sent to a text interpretation module 345 which filters the extracted text according to a predetermined set of rules to generate and output text in a predetermined format. The predetermined set of rules filter (or remove) invalid text formats so that only text in one of the predetermined formats is output. The predetermined formats are: (1) a single number, with or without metric units (e.g., 110, 110 cm, and 110 m); (2) a single number, with or without imperial units (e.g., 1, 1′, and 1″); (3) two numbers, each number being with or without units (e.g., 10×20 and 1″×2″); (4) a single piping acronym (e.g., HWS); (5) a single HVAC acronym (e.g., EA); (6) a combination of numbers+piping acronym; and (7) a combination of number+HVAC acronym.

The predetermined set of rules are based on acronyms used for pipe and duct systems, and equipment therefor, such as in plumbing and HVAC systems. The predetermined set of rules are applied to determine a system type (i.e., a duct or pipe system type), a size and/or equipment tag (as described more fully below). When the system type is a pipe system, the rules determine the size of the pipe diameter. When the system type is a duct system, the rules determine the size as either a diameter or by length and width because ducts can be round or rectangular.

The text interpretation module 345 outputs text and coordinates for each bounding box in the form of a system type and size for each bounding box for use in an amalgamation module 370, described below. The output text may be converted into a determined useable length and/or format.

The pixel tracing module 360 performs pixel tracing to perform pipe detection. However, before pixel tracing can be performed, pre-processing of the construction engineering drawing 301 is performed by a pre-processing module 350. The pre-processing module 350 removes noise from the construction engineering drawing 301 by applying a noise filter. The noise filter, in some embodiments, uses min pooling with a small kernel to remove background lines. In some embodiments, a kernel size of 2 is applied. The degradation of the foreground lines is then reversed with max pooling. The construction engineering drawing 301 outputs a pre-processed drawing which is sent to the pixel tracing module 360.

The pixel tracing module 360 receives the pre-processed drawing from the pre-processing module 350, the coordinates for the bounding box of the recognized text output from the CRNN 340, and the refined bounding box coordinates output from the coordinate refinement module 312. The bounding boxes coordinates of the recognized text output from the CRNN 340 and the refined bounding boxes from the coordinate refinement module 312 are used as the starting points for pixel tracing. For each horizontal bounding box, the algorithm searches for pipe segments starting from the center points of the left and right sides. For each vertical bounding box, the algorithm searches for pipe segments starting from the center points of the top and bottom sides. Diagonal bounding boxes are converted to horizontal or vertical boxes. A Hough Transform is used to find diagonal lines near diagonal bounding boxes. The angles of these diagonal lines are then stored and the most frequent angle is determined. The construction engineering drawing 301 is then rotated by the most frequent angle so that diagonal bounding boxes become horizontal or vertical bounding boxes.

The pixel tracing module 360 applies a non-NN approach to detect and trace pipes in the pre-processed drawing. The pixel tracing module 360 applies a detection algorithm that defines a process that detects horizontal and vertical continuous lines by tracing continuous black pixels starting from the bounding boxes of extracted text that describe a pipe diameter and/or pipe system type (the coordinates for each bounding box output from the CRNN 340) as well as bounding boxes for pipe fittings (the refined bounding box coordinates output from the CNN 310). The system applies a set of rules to reduce the bounding box content for analysis. The set of rules define limit the bounding box content for analysis to text strings that only apply to pipes and pipe fittings, such as predefined codes, numbers, and a diameter symbol. More details concerning these rules are described below. The pixel tracing module 360 determines the properties of lines representing each pipe or pipe section. Any dashed horizontal and vertical dashed lines are converted to continuous lines by using a series of morphological operations that include erosion and dilation operations which change dashed lines into solid or continuous lines. Dilation fills holes in an object. Erosion makes the boundaries of an object smooth. The pixel tracing module 360 uses dilation to join line segments (dashed lines). A side effect of this is that the top and bottom of the original line segments are thickened. The pixel tracing module 360 uses erosion to make the lines thinner with a line thickness similar to, or the same as, the line thickness before dilation. Any lines that are not horizontal or vertical relative to the orientation of the construction engineering drawing 301, i.e., lines that are at an angle relative to the horizontal and vertical axes of the construction engineering drawing 301 (“diagonal lines”), are converted to horizontal or vertical lines by rotating the pre-processed drawing. The same method is then applied to the converted lines. Each detected line has a corresponding bounding box. Diagonal lines are either parallel or perpendicular to diagonal bounding boxes. After diagonal bounding boxes are converted to horizontal or vertical bounding boxes, the lines perpendicular or parallel to them also become horizontal or vertical. The pixel tracing module 360 outputs the pipe coordinates of each detected pipe instance which are sent to the amalgamation module 370. The pipe coordinates are defined in terms of a start and end coordinates and optionally length (in pixels). The length of the pipe is defined implicitly by one or more line segments which comprise the pipe, each line segment defined by a starting point (x, y) and an end point (x, y).

The amalgamation module 370 performs pipe and pipe fitting amalgamation and duct and duct fitting amalgamation. The amalgamation module 370 receives system types and sizes output from the text interpretation module 345, the refined bounding box coordinates for detected ducts and fittings from the coordinate refinement module 312, and the pipe coordinates from the pixel tracing module 360. The amalgamation module 370 correlates the system type and size information with detected duct, fitting and pipe instances as well as the corresponding coordinates.

The correlated information is used to determine the coordinates, size and type of each detected duct, fitting and pipe instance. For example, size information determined for ducts and pipes are attributed to corresponding fittings of the respective ducts and pipes. For pipes, the amalgamation module 370 uses the coordinates of the pipes and the coordinates of the pipe fittings, assigns the attributes of the pipe (system type and diameter) to any fitting that intersects with the pipe itself.

The manner of correlation between fittings, ducts and pipes will now be briefly described. The text interpretation module 345 outputs a system size and/or system type for each text string. If a duct does not have a determined system and size, a check is performed to determine if the duct is connected to a non-reducer fitting that has a determined system and size. If so, the duct is assigned the same system type and system size as the non-reducer fitting. If not, user input/correction may be performed. For duct fittings, duct fittings are checked to see if the duct fitting is connected to any ducts that have a determined system type and system size. If so, the duct fitting is assigned the same system type and system size as the duct to which it is connected. If not, user input/correction may be performed.

For pipe fittings, each piping fitting output by the CNN 320 is checked to see if the respective pipe fitting is connected to any pipe output by the pixel tracing module 360. If so, the piping fitting is assigned the same system type and system size as the pipe to which it is connected. The system type and system size for pipes is determined by the pixel tracing module 360.

A record is generated for each recognized construction element (e.g., each duct, duct fitting, pipe, pipe fitting and equipment) recognized by the system 300 and each construction element added by a user. Each record is assigned a unique internal identifier (ID), such as an object ID, which uniquely identifies the respective construction element within the construction engineering drawing 301. Each record includes information about the construction element including the construction element type, construction element properties (system type, size, etc.) and a location within the construction engineering drawing 301 at which the construction element is located. When using a visual user interface (VUI) module 380 to view a visualization of the construction engineering drawing 301 annotated with detected or user added construction elements. The visualization represents construction elements as dynamic, selectable user interface objects having changeable properties which can be dynamically changed by a user. Using the visualization, construction elements may be added, deleted or changed (e.g., type, dimensions, etc.), with additions, deletions and changes automatically updating the corresponding data records, the list of construction elements and the visualization of the construction engineering drawing in real-time or near real-time as described more fully herein. The records of the construction elements are stored in a database maintained by the system 300. The database allows the records of the construction elements to be accessed and correlated in an efficient and effective manner when using the VUI. The new database structure permits the interaction with complex object maps occurring within construction engineering drawings and provides an efficient user correction process from which drawing takeoffs and construction estimates may be generated.

For ducts, amalgamation module 370 calculates a distance from the refined bounding box coordinates of the ducts output from the coordinate refinement module 312 to the bounding box coordinates for the system type and size indicators (also known as tags) output from the CRNN 340 to associate the system type and size indicators with a specific duct. There are two kinds of duct indicators, one inside the duct and the other outside. For an indicator that is inside a duct, the indicator is directly assigned to the duct based on the duct that it is inside. For an indicator that is not inside a duct, the indicator is assigned to the duct which is the shortest distance away. The output is a duct bounding box with coordinates, a length in pixels, a size, and a system type. The amalgamation module 370 uses the coordinates of fittings and the coordinates of ducts and assigns the attributes of the duct (system type and size) to any fitting that falls along the duct.

The system 300 also determines the length of each duct or pipe in real world dimensions. First, the size of the construction engineering drawing 301 is determined in terms of unit length (for example, in inches) from an image handling interface. Next, the size of the construction engineering drawing 301 is determined in pixels using the length of the drawing per unit length and the dots per inch (DPI) in which the drawing 301 is processed (for example, 150 dpi). Next, the length of each duct or pipe is determined using the Euclidean distance in pixels from the refined bounding box coordinates. This occurs via backend processing which is not visible to the user and is based on pixel calculations. Next, a size ratio of the element (duct or pipe) is determined as follows:

$$size ratio = \frac{length of element ( in pixels )}{length of drawing ( in pixels )} \qquad ( 1 )$$

Next, the length of the element in unit length (e.g., millimeters) is determined by applying the size ratio as follows:

$$length of element ( unit length ) = length of drawing * size ratio \qquad ( 2 )$$

Next, the scaled length of the element in real world dimensions is determined by applying the scale as follows:

$$s caled lengt h of element ( unit length ) = length of element ( unit length ) * scale \qquad ( 3 )$$

For metric scales, the scale value will be 1: XXXX, obtained from text recognition or user input. For imperial scales, the scale value may be obtained from text recognition or a dropdown with one of the following table of values, or a subset or derivation thereof:

TABLE 1
Architect's Scale (Imperial)

| Drawing Scale | Ratio | Common Use |
|---|---|---|
| Full Scale | 1:1 | Mock-ups/Samples/Small details |
| 3″ = 1′-0″ | 1:4 | Small Details |
| 1½″ = 1′-0″ | 1:8 | Small Details |
| 1″ = 1′-0″ | 1:12 | Small Details/Construction details |
| ¾″ = 1′-0″ | 1:16 | Construction details/Wall sections |
| ½″ = 1′-0″ | 1:24 | Building Sections |
| ⅜″ = 1′-0″ | 1:32 | Wall sections/Building Sections |
| ¼″ = 1′-0″ | 1:48 | Building Sections/Floor |
| | | plans/Elevations |
| 3/16″ = 1′-0″ | 1:64 | Floor plans/Elevations |
| ⅛″ = 1′-0″ | 1:96 | Floor plans/Elevations/Site plans |
| 3/32″ = 1′-0″ | 1:128 | — |
| 1/16″ = 1′-0′ | 1:192 | Site plans |

TABLE 2
Engineer's Scale (Imperial)

| Drawing Scale | Ratio | Common Use |
|---|---|---|
| 1″ = 10′-0″ | 120 | Details |
| 1″ = 20′-0″ | 240 | Details/Working Plans |
| 1″ = 30′-0″ | 360 | Working Plans |
| 1″ = 40′-0″ | 480 | Working Plans |
| 1″ = 50′-0″ | 600 | Working Plans |
| 1″ = 60′-0″ | 720 | Working Plans |
| 1″ = 010′-0″ | 1200 | Area Plans |

The length of the element may be converted between imperial/US units and metric using well known conversions at various stages. For example, when length measurements are made in inches, multiplying by 25.4 converts the length measurement from inches to millimeters (mm). Alternatively, a metric scale may be provided. The metric scale may be obtained from text recognition or a dropdown with a table of values similar those in Tables 1 and 2 above but in metric rather than imperial.

The amalgamation module 370 may estimate the size and system of a duct based on its pixel width by taking advantage of the fact that there is a positive correlation between the pixel width and the actual width of a duct for a given drawing. Ducts are divided into reliable ducts and unreliable ducts. Reliable ducts are ducts that contain duct labels. Both the pixel width and the actual width of a reliable duct are known. Unreliable ducts are ducts that do not contain any duct labels. Only the pixel width of an unreliable duct is known.

Using the pixel widths (x1, x2, . . . , xn) and actual widths (y1, y2, . . . , yn) of reliable ducts as data points, the amalgamation module 370 constructs a linear model that predicts the actual width (y) of an unreliable duct given its pixel width (x). After the actual width of an unreliable duct is estimated, the amalgamation module 370 attempts to locate its label by finding the nearest label that has the same actual width. Once the label of an unreliable duct is located, the duct inherits the size and system from that label.

The amalgamation module 370 then generates a first list of construction elements for all detected ducts and duct fittings which specifies the coordinates, size (diameter or height/width), length (for ducts only) system type and item type (for duct fittings only). The amalgamation module 370 also generates a second list of construction elements for all detected pipes and pipe fittings which specifies the coordinates, diameter, length (for pipes only) system type and item type (for pipe fittings only). The first and second lists may in turn be amalgamated or combined to generate a combined list of construction elements.

The first and second lists, or combined list of construction elements, may be output to a visual user interface (VUI) module 380 which may be used to display a visualization of the construction engineering drawing 301 and the first and second lists on a display of a user device 202, which is typically located remotely from the deep neural network-based system 300. Alternatively, the first and second lists, or combined list of construction elements may be output directly without a visualization.

The VUI module 380 may use the first and second lists, or combined list of construction elements, to generate an annotated construction engineering drawing (not shown). The annotated construction engineering drawing includes an image of the original construction engineering drawing 301 overlayed with user interface objects representing detected and user-added construction elements such as ducts, duct fittings, pipes, pipe fittings and equipment. The properties of the displayed user interface objects representing the construction elements can be viewed and edited by users. The VUI module 380 generates instructions for rendering and displaying on the display of the annotated construction engineering drawing within a VUI on the user device 202. The VUI module 380 represents ducts, duct fittings and pipe fittings as a series of bounding boxes and represents pipes as a series of lines. The bounding boxes and lines have the following attributes: coordinates, system type, item type, size and length. In some examples, the system types are either HVAC or piping. In some examples, for the HVAC system type, the item type is one of duct, elbow, center line reducer, supply air diffuser, eccentric reducer, perimeter diffuser, fire damper, return duct down (or return air grill), return duct, Y junction, supply or outside air duct, thermostat, manual balancing damper, round duct up, round duct down, meter, or motorized combination fire and smoke damper. In some examples, for the piping system type, the item type is one of ball value, gate value, Circuit balancing Valve (CBV), pipe down/endpoint A, butterfly valve, Automatic Control Valve (ACV), capped pipe, pipe up, solenoid valve, union, check valve, strainer, pump, valve and cap (V&C), backflow preventer, meter, thermometer, Motorized Ball Valve (MBV), pressure gauge, Pressure Relief Valve (PRV), or Safety Relief Valve (SRV).

The VUI showing the annotated construction engineering provides a number of operation or functions which can be applied. For example, the elements (e.g., ducts, duct fittings, pipes and pipe fittings) may be filtered to show or hide elements by system type and/or item type. The elements may also be color-coded according to system type and/or item type.

In some embodiments, the visualization of the annotated construction engineering drawing and the list(s) of materials may be used to correct information associated with an element such as a duct, duct fitting, pipe or pipe fitting. The correction may comprise any one or more of (i) adding missed fittings, ducts and pipes, (ii) removing incorrect fittings, ducts, and pipes, (iii) correcting the system type of fittings, ducts, and pipes, (iv) adding a missed system type or size for fittings, ducts, and pipes, (v) correcting the size of fittings, ducts, and pipes, (vi), adding a size of fittings, ducts, and pipes, and (vii) removing incorrect/irrelevant text detection and recognition results. Corrections are monitored and stored by the system 300 and can be used for further training and refinement of the neural networks of the system 300. For example, one or more of the first, second or third neural networks may be further trained by determining a training error as a difference between a respective prediction and the correction input by the user, and updating at least some parameters of the one or more of the first, second or third neural networks to minimize a training error through back propagation.

The backend processing of the system 300 includes generating a quantity takeoff and optionally a summary thereof for presentation to a user. The quantity takeoff comprises the following information or counts: (i) length of duct, broken out by size (diameter and height/width), and system type; (ii) length of pipe, broken out by diameter and system type; (iii) quantity of pipe fittings by type, size (diameter and height/width), and system type; and (iv) quantity of duct fittings by type, size (diameter and height/width), and system type. The VUI module 380 may be used to display the quantity takeoff or the summary thereof. The VUI module 380 may provide a “takeoff Summary” VUI screen which provides a sample material count. The takeoff Summary” VUI screen may be displayed before export to a third-party application, for example, such as Microsoft Excel or a costing application or other estimation application programming interface (API).

The system 300 provides an option to export one or any combination of the first list of construction elements, second list of construction elements, combined list of construction elements, the annotated construction engineering drawing (if a visualization of the annotated construction engineering drawing was generated), and the quantity takeoff. The exporting comprising formatting the selected data into one or more selected data types from a plurality of possible data types. The quantity takeoff may be exported into a .csv file used by common spreadsheet and word processing programs, an .xls file or similar file used by Microsoft Excel, a PDF file encoded with extensible Markup Language (XML) and/or labelled with headers, or a data export package for a third-party costing application or estimation API via an API provided by the front end of the system 300. Examples of third party costing applications or estimation APIs that exported data may be used with include those provided by Procore Technologies, Inc., Trimble Inc., and Autodesk, Inc.

The output data (e.g., quantity takeoff) is sent to a costing module 390, which receives the output data, such as one or any combination of the first list of construction elements, second list of construction elements, combined list of construction elements and quantity takeoff, and generates a cost estimation comprising a cost of materials for each element along with a total cost based on the individual cost of each element. The costing module 390 may be configured or trained with proprietary cost information. The cost information may be based on one or more of location information (i.e., construction site location, may be input by the user), vendors, trades, and/or other information.

The system 300 is also be configured to detect equipment construction elements in addition to HVAC construction elements and plumbing construction elements. Equipment construction elements in construction engineering drawings may lack a standard representative symbol. Similarity, text labels used in connection with equipment construction elements in construction engineering drawings may lack a standard syntax in terms of labelling, and therefore equipment construction element labelling cannot be learned by generalized learning techniques for text interpretation. As a result of these issues, the present disclosure provides a customized approach to recognizing equipment construction elements in construction engineering drawings that uses a pre-designated symbols and labelling syntax in combination with the object and text recognition pipeline applied to ducts, pipes and their fittings along with a customized interpretation algorithm to detect and recognize equipment, as described more fully herein.

The above-described system 300 provides a solution to analyzing construction engineering drawings that seeks to address some of the shortcomings of existing solutions such as conventional OCR and existing AI-assisted OCR. The system 300 comprises a network of neural networks which interact and cooperate with each other to recognize symbols, text, and lines, to interpret the recognized symbols, text, and lines as construction elements, and to generate a list of construction elements from the recognized construction elements. The neural networks of the system are trained individually or collectively to perform detection and recognition tasks. The outputs of these neural networks are combined with other drawing interpretation algorithms and rules to further interpret construction engineering drawings. The system also provides a dynamic, interactive visualization of the interpreted drawings that may be used to review the interpreted drawings to identify and correct errors, to provide a mechanism of authorization regulatory compliance (e.g., for professional regulatory compliance and/or enterprise compliance (e.g., for corporate approval compliance), or other reasons. The configuration of the system 300 is believed increase the speed and accuracy of computer-implemented construction engineering drawing interpretation while providing a means of user review and editing of interpretation results.

FIG. 6 is a flowchart of a method 600 of detection and classification of construction elements in construction engineering drawings in accordance with an embodiment of the present disclosure. The method 600 is performed at least in part by the system 300 described above in connection with FIG. 3.

At step 602, the system 900 receives a construction engineering drawing 301 from a user device 202 via the communication network 240. The system 900 and user device 202 communicate via a client-server relationship with the user device 202 acting as a thin client via a local software application. The construction engineering drawing 301 may be uploaded from the user device 202 via a user interface of the local software application, which may be a Web-based or browser-based application in one of a number of different formats such as a PDF, image, or Computer aided design (CAD) file.

At step 604, the system 900 optionally converts the construction engineering drawing 301 to an image in response to the construction engineering drawing 301 being provided in a format other than an image file. The construction engineering drawing 301 may be converted into a binary image consisting of black and white pixels.

At step 606, the system 300 performs object detection and recognition to detect and recognize ducts and fittings in a construction engineering drawing via a first neural network such as the CNN 310. The first neural network outputs bounding box coordinates for each detected duct and fitting instance.

At step 608, the system 300 performs text detection to detect text in the construction engineering drawing 301 via a second neural network such as the CRAFT CNN 320. The second neural network outputs bounding box coordinates for detected text.

At step 609, the system 300 performs text recognition upon the detected text to recognize the detected text via third neural network such as the CRNN 340. The third neural network outputs recognized text and the bounding box coordinates thereof. Although in the present embodiment steps 608 and 609 are performed as separate steps, the text detection and recognition may occur in one step in other embodiments.

At step 610, the system 300 filters the recognized text in accordance with a predetermined set of rules to output system types and system sizes from the recognized text.

At step 612, the system 300 performs pixel tracing of the construction engineering drawing 301 using the bounding box for detected text as a reference point to use to determine a location to start pixel tracing, as described above. The pixel tracing outputs pipe coordinates for each detected pipe instance.

At step 614, the system 300 correlates each system type and size instance to a detected duct, pipe or fitting instance to generate coordinates, system type, item type, size and length for each respective duct, pipe or fitting instance. In some examples, the system types are either HVAC or piping. In some examples, for the HVAC system type, the item type is one of duct, elbow, center line reducer, supply air diffuser, eccentric reducer, perimeter diffuser, fire damper, return duct down, return duct, Y junction, supply or outside air duct, manual balancing damper, round duct up, round duct down, meter, or motorized combination fire and smoke damper. In some examples, for the piping system type, the item type is one of ball value, gate value, CBV, pipe down/endpoint A, butterfly valve, ACV, capped pipe, pipe up, solenoid valve, union, check valve, strainer, pump, V&C provision, backflow preventer, meter, thermometer, MBV, pressure gauge, PRV, or SRV.

At step 616, the system 300 generates a list of construction elements for all detected duct, pipe and fitting instances, wherein the list of construction elements specifies coordinates, size, length, system type and optionally item type for each respective duct, pipe or fitting instance. The list of construction elements may be provided by a quantity takeoff. Alternatively, a quantity takeoff may be generated from the list of construction elements. The quantity takeoff may comprise the following information or counts: (i) length of duct, broken out by size (diameter and height/width), and system type; (ii) length of pipe, broken out by diameter and system type; (iii) quantity of pipe fittings by type, size (diameter and height/width), and system type; and (iv) quantity of duct fittings by type, size (diameter and height/width), and system type.

At step 618, the system 300 may optionally generate an annotated construction engineering drawing based on the construction engineering drawing and the list of construction elements, which may be displayed on a user device 202.

At step 620, the system 300 may optionally receive corrections to detections via user input received from the user device 202 and may optionally fine-tune or (re) train one or more of the first, second or third neural networks by updating at least some parameters of the one or more of the first, second or third neural networks to minimize a training error through back propagation.

At step 622, the system 300 may optionally generate a cost estimation comprising cost of materials for each detected duct, pipe or fitting instance along with a total cost based on an individual cost of each duct, pipe or fitting instance based on the list of construction elements.

At step 624, the system 300 outputs data such as one or a combination of a first, second or combined list of construction elements, annotated construction engineering drawing, or cost estimation. In some embodiments, the outputting may comprise instructing the user device 202 to provide, on a display of the user device 202, an interactive visualization of the construction engineering drawing annotated within a visual user interface displayed on the display of the user computing device, wherein the annotated construction engineering drawing comprises an editable visual interface element for each detected construction element instance in the list of construction elements. The interactive visualization represents each detected construction element as a dynamic, selectable visual interface element having changeable properties. In some embodiments, the interactive visualization provides real-time interactions between the user computing device and the DNN-based system. In some embodiments, the instructing comprises sending, via the communication network, the annotated construction engineering drawing to the user device 202 with instructions which, when executed by the processor(s) 102 of the user device 202, cause the interactive visualization of the annotated construction engineering to be displayed on the display thereof.

The outputting may comprise generating the annotated construction engineering drawing based on the construction engineering drawing and the list of construction elements.

The outputting comprises communicating the list of construction elements to a cost module via an application programming interface (API), wherein the cost estimate is generated by the cost module which returns the cost estimation via the API. In such embodiments, the cost module is provided by a third party and is separate from the deep neural network-based system 300. The method

In other embodiments, the method 600 may further comprise generating a cost estimation comprising a cost of materials for each detected duct, pipe or fitting instance along with a total cost based on an individual cost of each duct, pipe and fitting instance based on the list of construction elements. In other embodiments, the cost estimation may further comprise a cost of materials for each detected equipment instance. The method 600 may further comprise instructing the user computing device to provide the cost estimation to the user computing device, wherein the instructing comprises sending, via the communication network, the cost estimation to the user computing device with instructions which, when executed by the user computing device, cause the cost estimation to be displayed on the display thereof.

The method 600 further comprise changing parameters of recognized construction elements, adding construction elements and removing construction elements in response to corresponding user input via the visual user interface provided on the display of the user computing device, wherein changes, additions and removals automatically update the list of construction elements, corresponding data records and the visualization of the construction engineering drawing in real-time.

In some embodiments, the construction element type associated with the recognized text is determined by: matching the bounding box coordinates of the recognized text with the bounding box coordinates or pipe coordinates of a matching detected duct, duct fitting, pipe, pipe fitting or equipment instance; and determining the construction element type associated with the matching detected duct, duct fitting, pipe, pipe fitting or equipment instance.

In some embodiments, the bounding box coordinates of the recognized text are determined to match the bounding box coordinates or pipe coordinates of a detected duct, duct fitting, pipe, pipe fitting or equipment instance when the coordinates are within a threshold distance from each other.

In some embodiments, each construction element is defined by a data record stored in a database managed by the system, each data record in the database comprising a corresponding object identifier (ID) which uniquely identifies the respective construction element within the construction engineering drawing and information about the respective construction element including the construction element type, construction element properties and a location within the construction engineering drawing at which the construction element is located.

In some embodiments, a data record is generated and stored for each construction element detected by the DNN-based system or added by a user.

In some embodiments, the method 600 further comprises: calculating a training error based on a difference between a system generated data entry and a user corrected data entry for the system generated data entry; and training the system updating one or more parameters of a neural network of the system based on the training error. Details regarding the training in some embodiments is provided later herein.

The steps and/or operations in the flowcharts and drawings described herein are for purposes of example only. There may be many variations to these steps and/or operations without departing from the teachings of the present disclosure. For instance, the steps may be performed in a differing order, or steps may be added, deleted, or modified, as appropriate.

### Drawing Interpretation Rulesets

The system 300 is trained to apply drawing interpretation rulesets to asset in the interpretation of construction engineering drawings in some embodiments. The drawing interpretation rulesets are based on interpretation rules for construction engineering drawings. An example of a drawing interpretation ruleset that may be applied by the system 300 is for lead lines/arrows associated with fittings that define one or both of a size and system type.

As part of normal processing, the system 300 detects (i) lead lines, either with or without arrows, in a drawing 301 and generates a bounding box for the detected lead lines, (ii) text in the drawing 301 and generates a bounding box for the detected text, and (iii) fittings and in the drawing 301 and generates a bounding box for the detected fittings. If the bounding box for a lead line overlaps with the bounding box for text and the bounding box for a fitting, the text of the bounding box is associated with the fitting by the system 300, and the text is interpreted accordingly. The system 300 may determine one or both of a size and system type of the fitting from the associated text, the system may the one or both of a size and system type.

### Visualization/User Interface

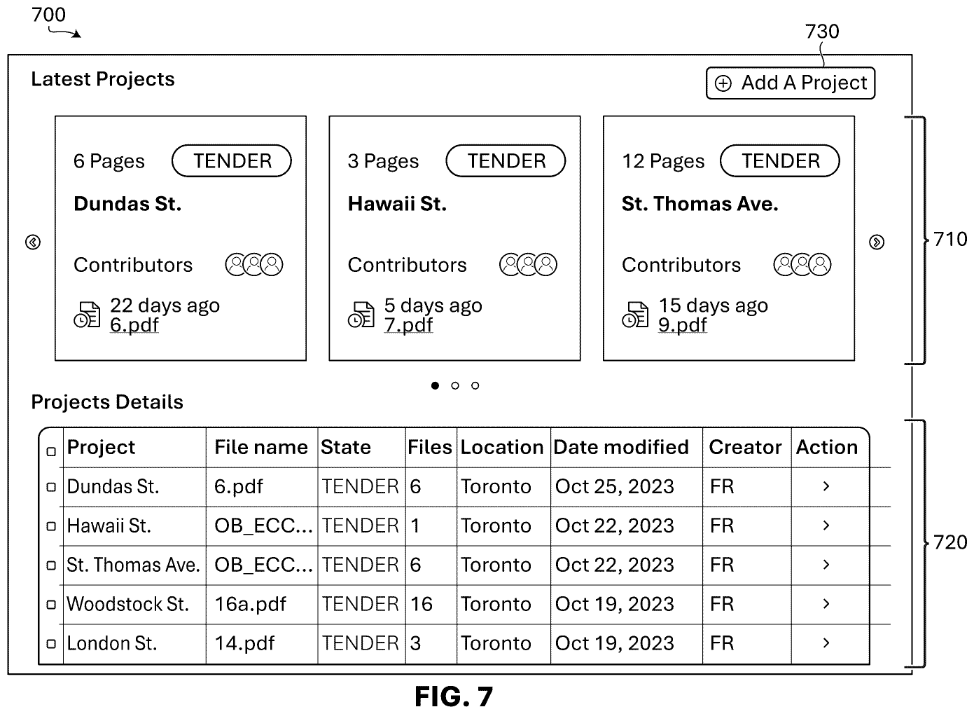

Referring now to FIG. 7-18, an example user interface screens of the user front end application 250 for communicating and interacting with the system 300 will be described. FIG. 7 is an example of a home (or main) screen 700 of the application 250. The application 250 may be a Web-based application executed from an Internet browser operating on a user device 202. The home screen 700 may be displayed upon logging or otherwise accessing the application 250 from an Internet browser operating on a user device 202. Access to the application 250 typically requires authentication of an authorized user using a user name and password or other suitable authentication means.

The home screen 700 includes a first portion 710 in which active or recent projects are displayed and second portion 720 in which project details are displayed. In the shown example, each active project is represented in the first portion 710 as a panel or pain with limited project details such as name or title, file name, date of last modification or creation, size (e.g., pages), status, and contributors. The first portion 710 may be implemented as a rotating carousel or panel which can be navigated and a project may be selected for editing via corresponding input. The second portion 720 typical includes the project details of the first portion 710 as well as additional details such as location as well as selectable actions. The selectable actions may include changing project status, opening the respective project, and deleting the respective protect. The possible values of the project status include tracking, tendered, submitted and completed. A project value of “tracking” indicates a project that is being monitored but which may not be analyzed, costed or tendered. A project value of “tendered” indicates a project that has been costed but has not yet been submitted. A project value of “submitted” indicates a project that has been costed and submitted for tender but is still awaiting a tender decision. A project value of “completed” indicates a project that has been analyze and costed and but not yet submitted for tendered. The home screen 700 also includes an onscreen button 730 for adding or creating a new project.

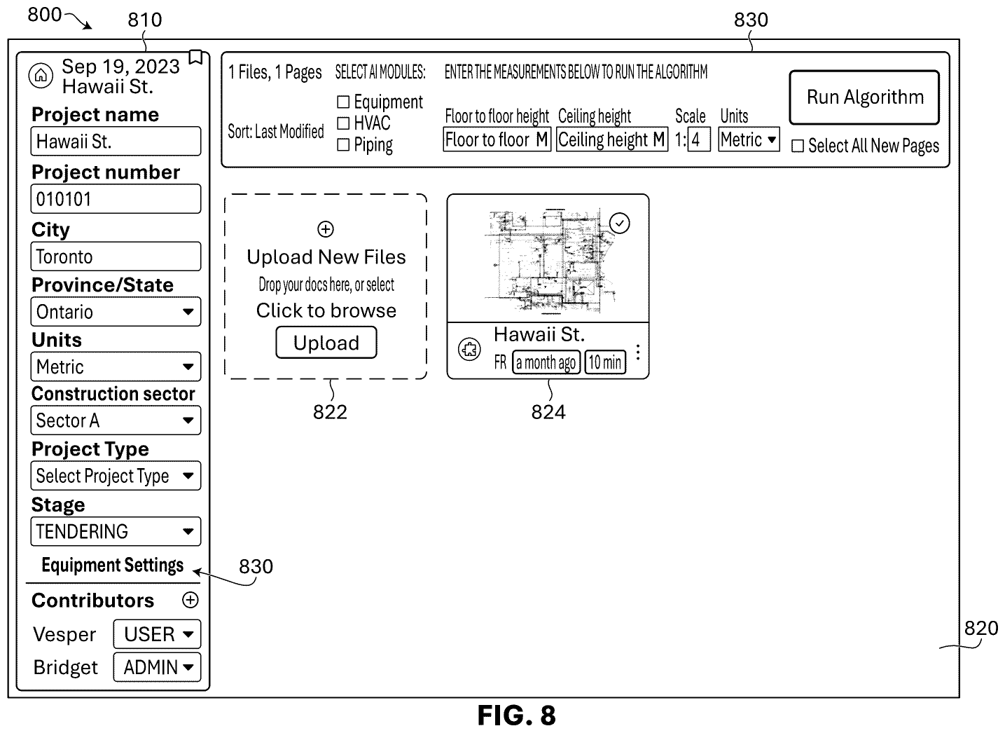

FIG. 8 is an example of a project screen 800 of the application 250. The screen 800 is invoked and displayed in response to selection of a respective project from the home screen 700. The project screen 800 includes a project panel 810 which includes information about the project, a canvas area 820 and a taskbar (or toolbar) 830 for defining project specifications and selecting one or more AI modules to be applied to a respective project. The canvas area 820 includes icons or other representations such as drawing panels 822 (only one of which is shown in FIG. 8) in which uploaded construction engineering drawings are displayed and a panel 824 for uploading a new construction engineering drawing. An uploaded construction engineering drawing may be selected for display and optionally editing by selecting a corresponding drawing panel 822 from the canvas 820. Settings for equipment recognition can be set or edited via an Equipment Settings window which can be invoked and displayed by selecting a corresponding Equipment Settings window element 830 on the project screen 800.

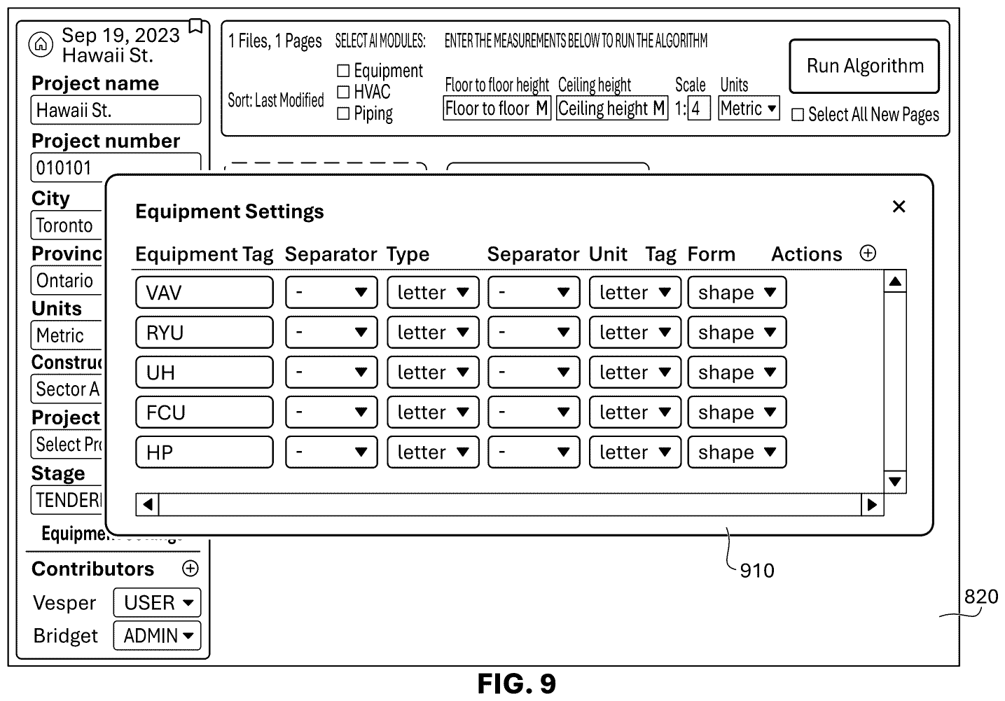

FIG. 9 shows the project screen 800 with the Equipment Settings window 910 displayed. As noted above, the Equipment Settings window 910 which can be invoked and displayed by selecting a corresponding Equipment Settings window element 830 on the project screen 800. The Equipment Settings window allows users to define settings for equipment to be recognized based on a text-based equipment tag (or label). The settings allow each type of construction equipment to be recognized as an equipment tag of defined format or syntax. The equipment tag comprises (i) an equipment tag prefix, (ii) a type, and (iii) a unit, each separated by a separator. Each equipment tag has a tag form. The equipment tag prefix can be anything but some common prefixes are: Variable Air Volume (VAV), Air Handling Unit (AHU), Vertical Unit Ventilator (VUV), Heat Pump (HP) and Fan Coil Unit (FCU).

The equipment tag prefix may have a maximum length, such as 6 characters. The type will either be a number code, or a letter, for example VAV-2 or VAV-A. The Unit will either be a number code, or a letter, for example VAV-2-A or VAV-A-2. The separator can be a dash, period, space or slash. The tag form is either shape or text. When the tag form is a shape, a defined shape or symbol associated with the equipment tag will be detected and recognized by the first CNN 310. The detected shape or symbol is then associated with recognized text output from the CRNN 340, and the recognized text is determined to be an equipment tag. The text interpretation module 345 is then used on the recognized text associated with the detected shape or symbol to identify an equipment tag from the recognized text using predetermined rules of the text interpretation module 345 for equipment tags. The equipment tag symbol may be the same for all equipment types or different. In some examples, the defined shape or symbol is a hexagon and the first CNN 310 will detect and recognize equipment tags within a hexagon. In other examples, the defined shape or symbol may be a diamond or other suitable shape or symbol. Any other lines or shapes within the defined shape or symbol will be ignored. When the tag form is a text, the system 300 analyses detected text without any assistance by a previous step of shape/symbol detection.

The associated symbol is used to detect and localize the construction equipment tags within the drawing. The Equipment Settings window 910 includes an Action button which allows equipment definitions to be saved/stored or deleted. Construction equipment tags and the symbols associated therewith that are used in construction engineering drawings may vary by draftsperson, project, enterprise or other factor(s). Advantageously, the system 300 of the present disclosure provides a mechanism for recognizing construction equipment based on user defined format and syntax and text-symbols associations rather than a learned syntax, which is different to learn given the inherent variability of the data.

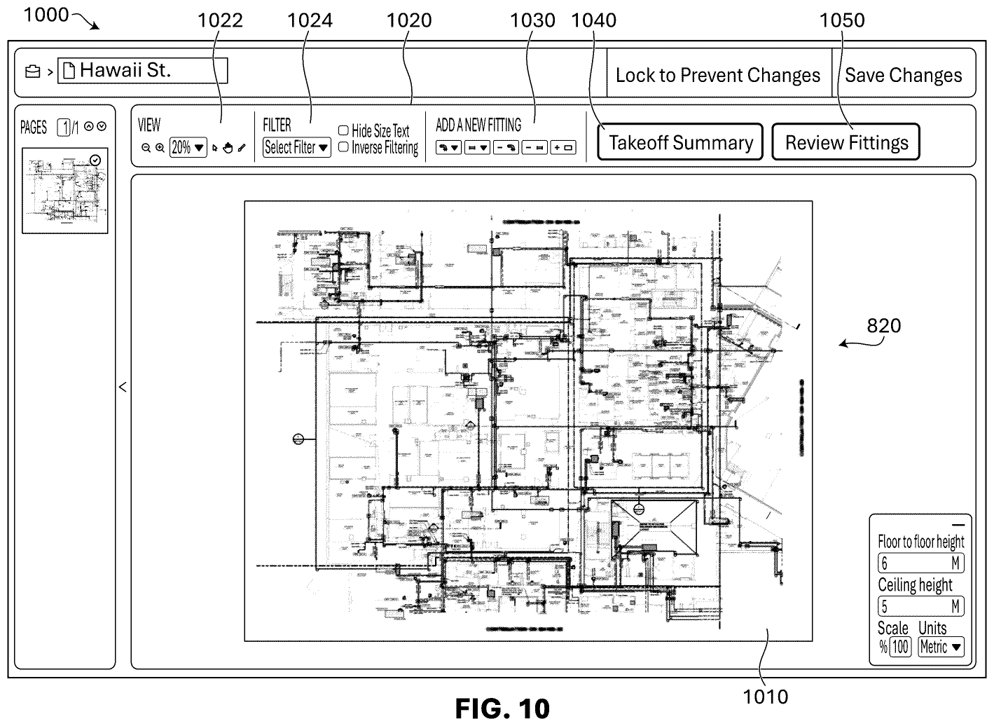

FIG. 10 is an example of a drawing screen 1000 of the application 250. The drawing user interface screen 1000 is displayed after selecting a corresponding drawing panel 822 from the canvas 820. In the shown embodiment, an annotated construction drawing 1010 is displayed within a canvas area of the drawing screen 1000. In the shown example, the annotated construction drawing 1010 has already undergone recognition and comprises the imported or uploaded construction engineering drawing 301 in the form of an image annotated with detected construction elements displayed thereon. Each detected construction element is represented by a dynamic, selectable object of a corresponding visualization type. The visualization type may vary in accordance its construction element type. For example, ducts, duct fittings, pipes, pipe fittings and equipment are each represented by a corresponding visualization type, which may vary based on the type of construction element. In some examples, each duct length is represented by a corresponding box which overlays the respective duct whereas each pipe length is represented by a corresponding line segment which overlays the respective pipe length.

In some user interface modes, each duct length and pipe length is displayed in a color representing whether the length of duct or pipe has been fully detected and recognized. In the entire length has been fully detected and recognized, the duct or pipe is shown in a first color (e.g., green). In the entire length has been fully detected and recognized, the duct or pipe is shown in a second color (e.g., blue). This provides a visualization that readily informs the user that user correction to add any missing length(s) and/or fitting(s) or correct that the length is in fact complete.

In other user interface modes, each construction element type may be displayed in a color representing the corresponding system type so that each system type may be more easily identified and reviewed by a user. As described elsewhere herein, the VUI provides a filtering option which may allow the recognized construction elements to be displayed based on the system type, construction element type (e.g., ducts, duct fittings, pipes, pipe fittings, equipment) and/or fitting type (if applicable). The color associated with each system type may be configurable by the user via application settings.

Each duct fitting and pipe fitting is represented by a corresponding bounding box which overlays the respective duct or pipe fitting. The corresponding bounding box may be represented with a lined perimeter and a semi-transparent or fully transparent (e.g., clear) interior so that the respective duct or pipe fitting symbol in the displayed construction engineering drawing can been seen. Each displayed visualization (e.g., line or corresponding bounding box) may be displayed at the same or similar positions to the corresponding displayed detected construction elements in the displayed construction engineering drawing 301.

The drawing screen 1000 includes a taskbar (or toolbar) 1020 which includes a view portion 1022 which includes icons for causing a decrease in the zoom level, an increase in the zoom level, setting a specified zoom level, selecting a recognized object in the drawing, moving the drawing within the canvas 820, and changing the properties of the recognized object (such as whether the object is a duct or pipe and the corresponding system type. A recognized object is selected by single clicking the visualization of the recognized object with a pointing tool such as a mouse. This causes a properties window to be displayed, in which object properties can be edited (changed and saved). The selection of the recognized object causes the visualization of the recognized object to be emphasized or highlighted, for example, by changing the color of the visualization. Connection points of the visualization of the recognized object may also be displayed in response to selection, for example, endpoints and a center point of a line segment may be displayed (for pipes) and corners of a bounding box may be displayed. While a recognized object is selected, it can be moved within the drawing by corresponding input, such as moving the point tool (e.g., mouse) while holding down a control button (e.g., left mouse button). Double clicking the visualization of the recognized object with a pointing tool selects the recognized object and increases the zoom level of the drawing centered around the recognized object. This can be done repeatedly to repeatedly increase the zoom level. Scrolling input with a scrolling tool such as a mouse causes the zoom level of the construction engineering drawing to be increased or decreased based on the scrolling direction.

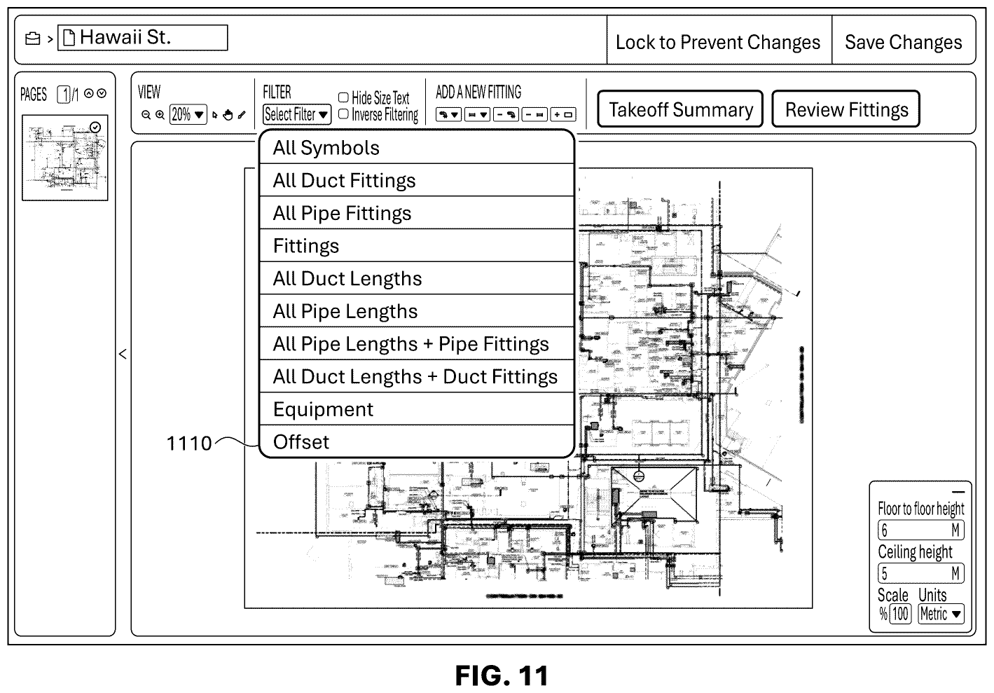

The taskbar 1020 also includes a filter portion 124 which includes a dropdown menu for selecting one or more filters to be applied to the active construction drawing, hiding size text, and inverse filtering. The selected filters are described below in connection with FIG. 11. The action of hiding size text causes the size of the respective construction element to be hidden from the display. The action of inverse filtering removes all the construction elements that have detected by the system 300 so that only any undetected construction elements are displayed. This facilitates the user addition of any undetected construction elements.

The taskbar 1020 also includes a construction element portion 1030 which includes icons for invoking dropdown menus for selecting a corresponding addition for adding or modifying construction elements, the selection of which causes a response action to be performed. In the shown embodiment, the taskbar 1020 also includes an icon for adding a duct fitting, adding a pipe fitting, adding a duct length, adding a pipe length, and adding equipment. In at least some embodiments, only pre-defined duct fittings or pipe fittings can be added. The system includes information about pre-defined duct fittings or pipe fittings such as properties and a thumbnail image for use during review. The taskbar 1020 also includes a Takeoff Summary (or Drawing Takeoff Report) onscreen button 1040 for invoking and displaying a Takeoff Summary and a Review Element onscreen button 1050 for invoking and displaying a Takeoff Review Element user interface. The inverse filtering option removes construction elements that were detected, leaving only construction elements that were added.

FIG. 11 shows the drawing screen 1000 with a filter menu 1110 displayed after selecting the dropdown menu for selecting one or more filters to be applied to the active construction drawing from the taskbar 1020. In the shown example, the filters that can be applied include all symbols, all duct fittings, all pipe fittings, selected fittings, all duct lengths, all pipe lengths, all pipe lengths and pipe fittings, all ducts and duct fittings, equipment, and offset. An offset occurs when two construction elements cross over each other. One construction element needs to drop below or “offset” the other construction elements. Each offset has a length and a pair of elbows. Selected fittings may be selected via a hierarchical menu in which, when fitting is selected, the fitting menu option is expanded to provide an option to select either duct or pipe, and after either duct or pipe is selected, a corresponding menu of either duct fittings or pipe fittings is provided, thereby allowing the user to select individual duct fittings or pipe fittings.

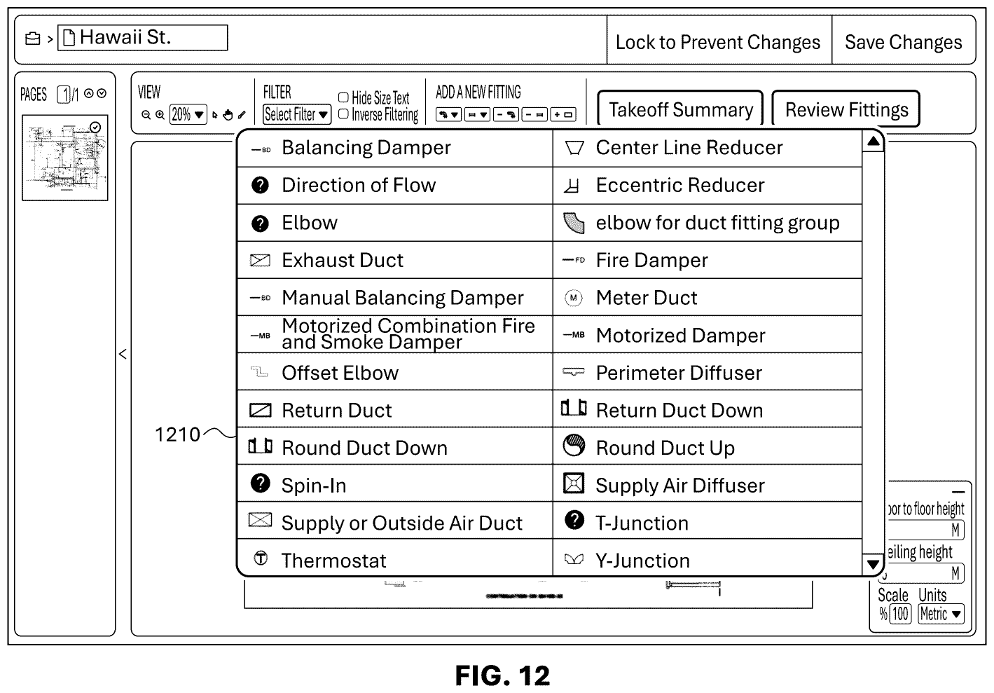

FIG. 12 shows the drawing screen 1000 with an Add Duct Fitting menu 1210 displayed after selecting the add duct fitting icon from the taskbar 1020. In the shown embodiment, the Add Duct Fitting menu 1210 allows the selection of a duct fitting to be added from the group consisting of any two or more of balancing damper, center line reducer, direction of flow, eccentric reducer, elbow, elbow for duct fitting group, exhaust duct, fire damper, manual balancing damper, meter duct, motorized combination fire and smoke damper, motorized damper, offset below, perimeter diffuser, return duct, return duct down, round duct down, round duct up, spin-in supper air diffuser, supper or outside air duct, T-Junction, thermostat, and Y-junction. After selecting a duct fitting, a duct fitting menu is displayed which prompts the user to specify a system type and a diameter or cross-section, depending on the duct fitting type.

A menu option for selecting either a round or rectangle duct cross-section may be provided depending on the duct fitting type, which may then dynamically set or change the prompt for a diameter or cross-section of the duct fitting. After specifying the information requested in the duct fitting menu by the prompts, the duct fitting may be added to the active construction drawing by moving a cursor or pointer to a corresponding location of the drawing via a navigation input tool such as a mouse and clicking or selecting the corresponding location on the of the drawing via the navigation input tool. Clicking or selecting the corresponding location on the of the drawing will place a UI element corresponding to the added duct fitting on the drawing at the corresponding location as well as invoke and display a Fitting Properties UI screen. The Fitting Properties UI screen displays the Fitting Properties in an editable form and includes onscreen buttons to correct or delete the added duct fitting.

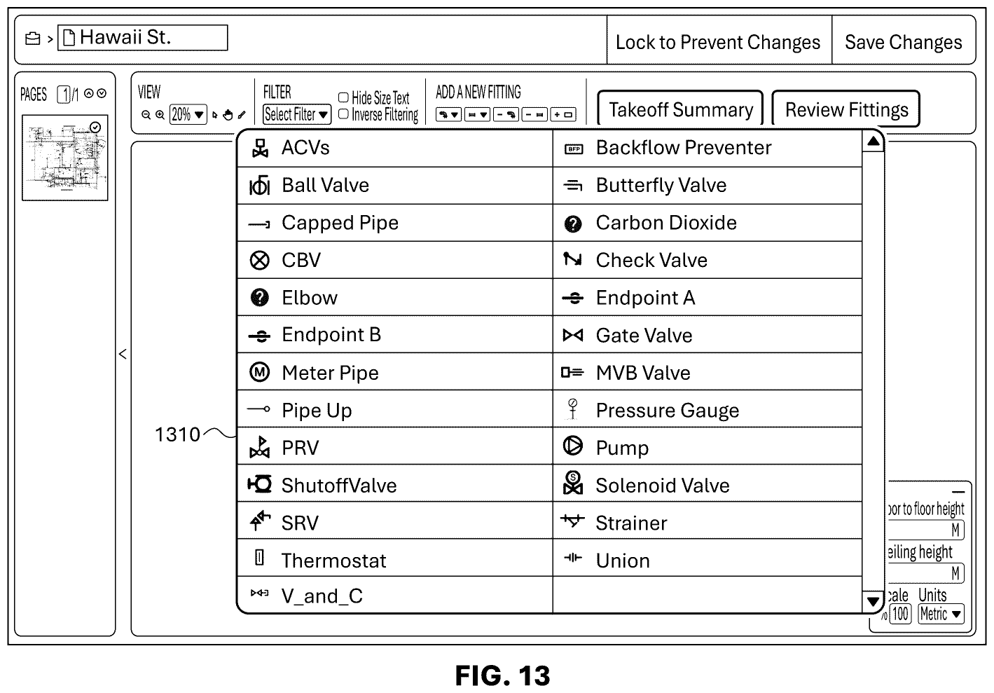

FIG. 13 shows the drawing screen 1000 with an Add Pipe Fitting menu 1310 displayed after selecting the add duct fitting icon from the taskbar 1020. In the shown embodiment, the Add Duct Fitting menu 1210 allows the selection of a duct fitting to be added from the group consisting of any one or more of ACV, backflow preventer, ball valve, butterfly valve, capped pipe, carbon dioxide, CBV, check valve, elbow, endpoint A, endpoint B, meter pipe, MVB valve, pipe up, pressure gauge, PRV, pump, shutoff valve, solenoid valve, SR, strainer, thermometer, union, and V&C. After selecting a pipe fitting, a pipe fitting menu is displayed which prompts the user to specify a system type and a diameter of the pipe fitting.

After specifying the information requested in the pipe fitting menu by the prompts, the pipe fitting may be added to the active construction drawing by moving a cursor or pointer to a corresponding location of the drawing via a navigation input tool such as a mouse and clicking or selecting the corresponding location on the of the drawing via the navigation input tool. Clicking or selecting the corresponding location on the of the drawing will place a UI element corresponding to the added pipe fitting on the drawing at the corresponding location as well as invoke and display a Fitting Properties UI screen. The Fitting Properties UI screen displays the Fitting Properties in an editable form and includes onscreen buttons to correct or delete the added pipe fitting.

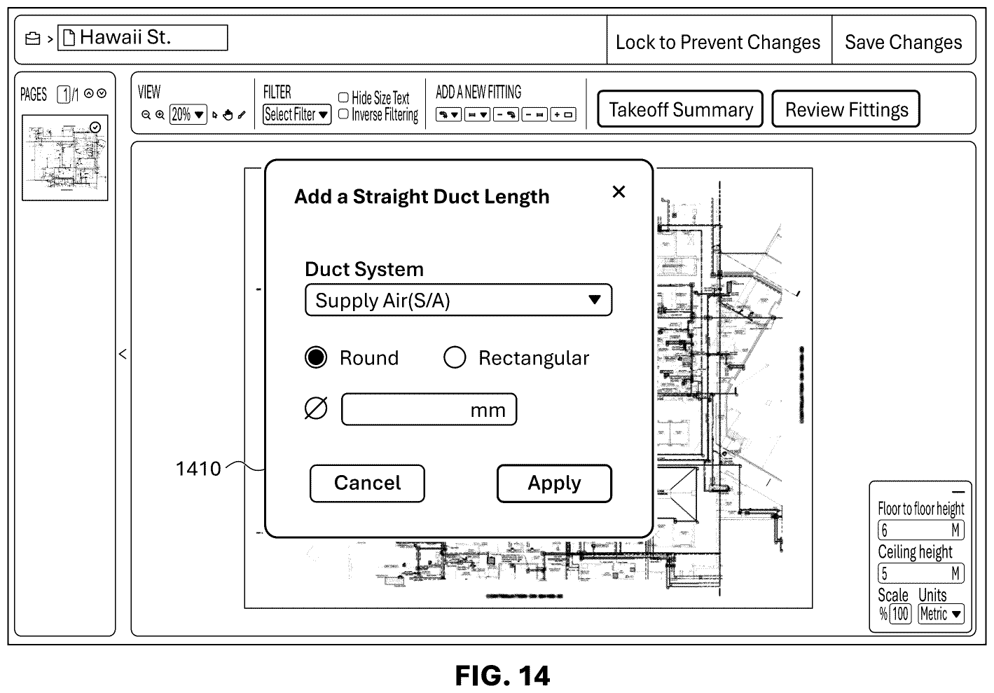

FIG. 14 shows the drawing screen 1000 with an Add Duct Length menu 1410 displayed after selecting the add duct length icon from the taskbar 1020. The Add Duct Length menu 1410 prompts the user to specify a system type and a diameter or cross-section, depending on the duct type. A menu option for selecting either a round or rectangle duct cross-section may be provided depending on the duct type, which may then dynamically set or change the prompt for a diameter or cross-section of the duct.

After specifying the information requested in the Add Duct Length window 1410 by the prompts, the duct may be added to the active construction drawing by moving a cursor or pointer to a corresponding start location of the drawing via a navigation input tool such as a mouse and clicking or selecting the corresponding location on the of the drawing via the navigation input tool. Clicking or selecting a corresponding end location on the drawing will complete the duct length. The length of the added duct will be determined automatically by the application 250 based on the distance between the start and end locations and the drawing scale. A Duct Properties UI screen will also be invoked and displayed. The Duct Properties UI screen displays the duct properties in an editable form and includes onscreen buttons to correct or delete the added duct fitting.

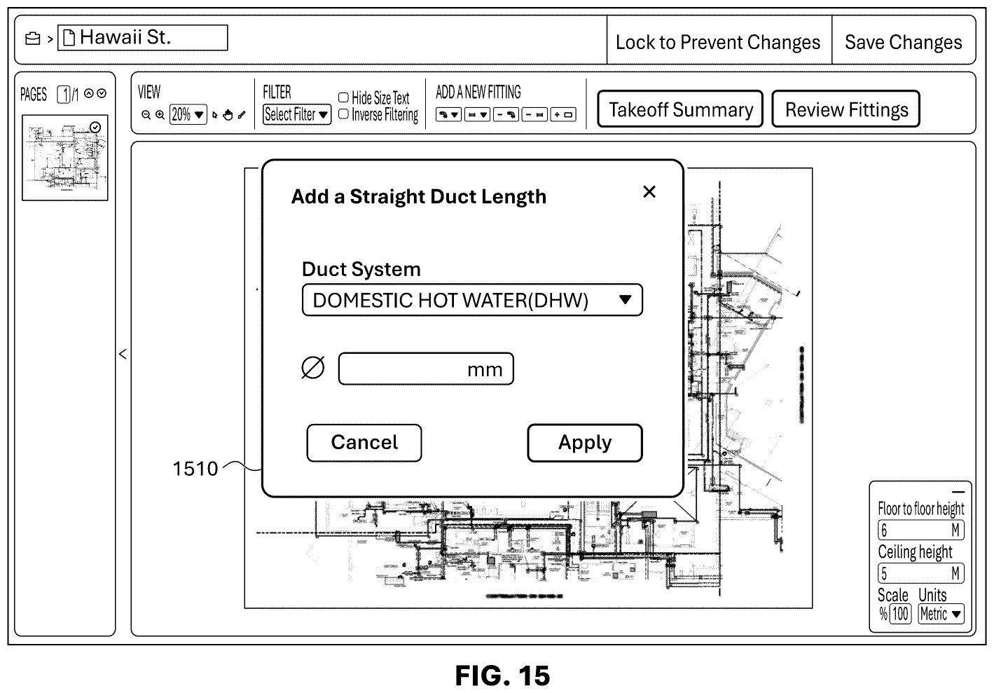

FIG. 15 shows the drawing screen 1000 with an Add Pipe Length window 1510 displayed after selecting the add pipe length icon from the taskbar 1020. The Add Pipe Length window prompts the user to specify a system type and a diameter of the pipe. After specifying the information requested in the Add Pipe Length window 1410 by the prompts, the pipe may be added to the active construction drawing by moving a cursor or pointer to a corresponding start location of the drawing via a navigation input tool such as a mouse and clicking or selecting the corresponding location on the of the drawing via the navigation input tool. Clicking or selecting a corresponding end location on the drawing will complete the pipe length. The length of the added pipe will be determined automatically by the application 250 based on the distance between the start and end locations and the drawing scale. A Pipe Properties UI screen will also be invoked and displayed. The Pipe Properties UI screen displays the pipe properties in an editable form and includes onscreen buttons to correct or delete the added pipe fitting.

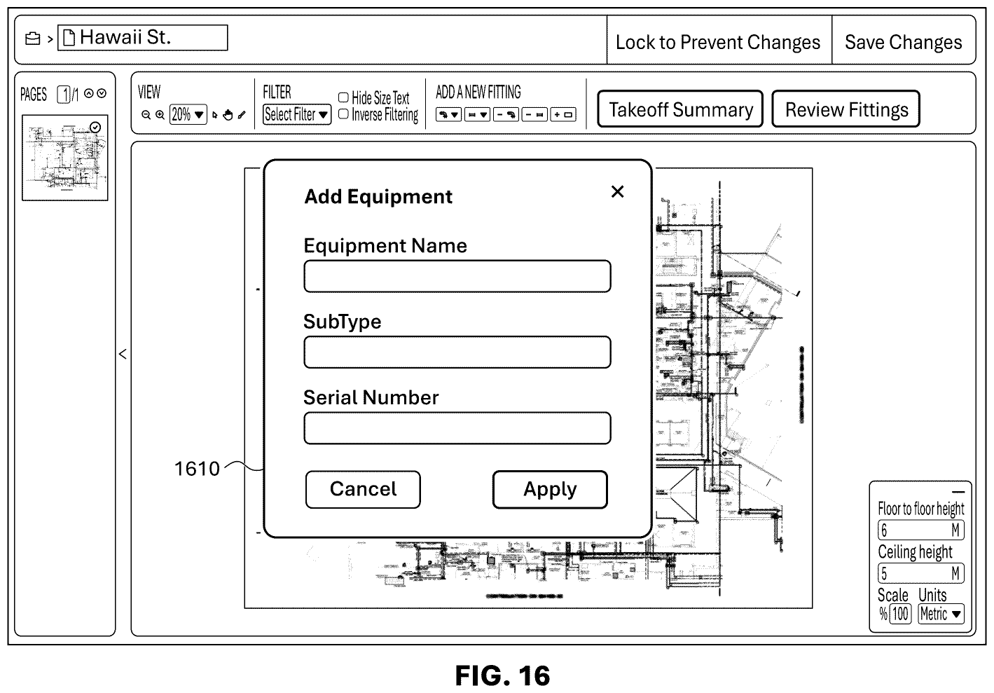

FIG. 16 shows the drawing screen 1000 with an Add Equipment window 1610 displayed after selecting the add equipment icon from the taskbar 1020. The Add Equipment window 1610 prompts the user to specify the equipment name, a type (or subtype) and serial number, in the same format that equipment tags are defined in the Equipment Settings window 910 (FIG. 9), as described above.

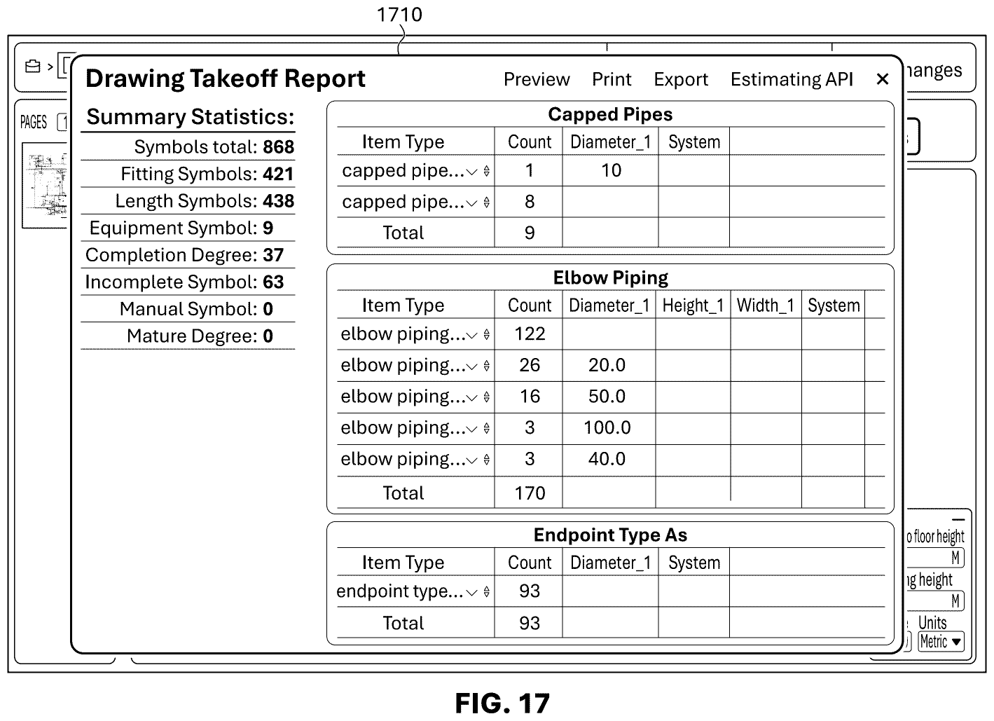

FIG. 17 shows the drawing screen 1000 with a Takeoff Summary window 1710 displayed after selecting the Takeoff Summary icon 1030 from the taskbar 1020. The Takeoff Summary window 1710 provides a listing of construction elements for the drawing, including construction elements automatically recognized by the system 300 and user-added construction elements, as well as statistics and estimation options. In the shown embodiment, the Takeoff Summary window 1710 includes a preview onscreen button for providing a condensed or rolled-up takeoff summary as opposed to a detailed takeoff summary, a print onscreen button for printing the takeoff summary, an export onscreen button for exporting the takeoff summary into one of CSV, Excel, Google Docs, or PDF formats, and estimate onscreen button for generating the cost of the takeoff summary using an estimation API selected from one of APIs for Audodesk™, Trimble™ and Quotesoft™ estimation platforms. Selecting the preview onscreen button toggles between the detailed takeoff summary and condensed takeoff summary. In other embodiments, the estimation may be generated by an internal module or may be part of the system 300.

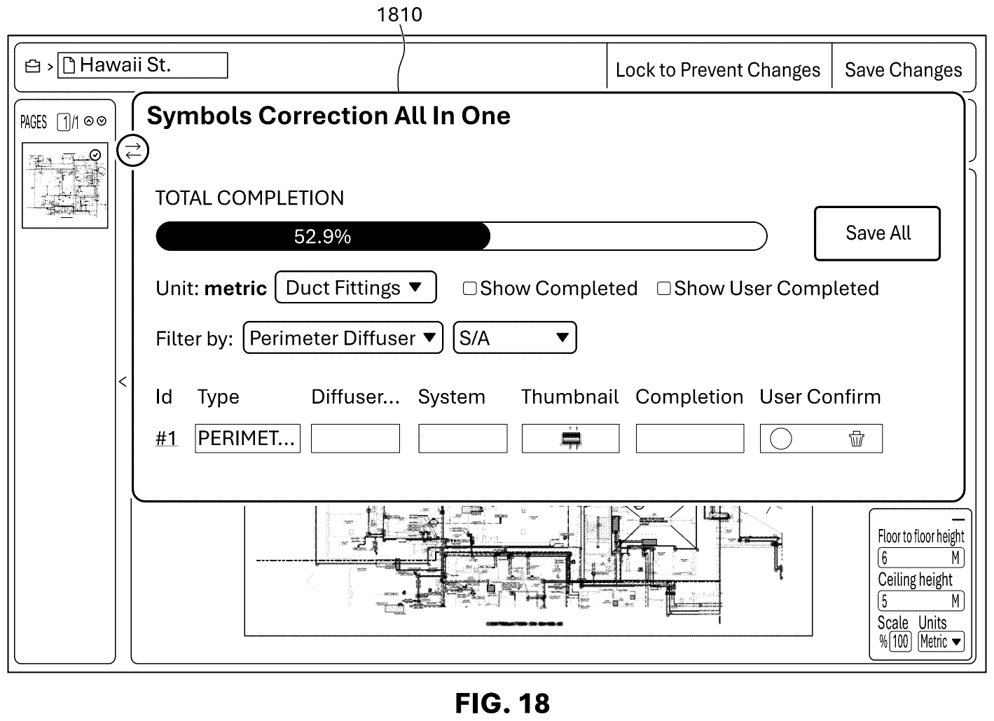

FIG. 18 shows the drawing screen 1000 with a Review Element window 1810 displayed after selecting the Review Element icon 1040 from the taskbar 1020. The Review Element window 1810 includes a dropdown menu for selecting construction element types (e.g., duct fittings, pipe fittings, duct lengths, pipe lengths and equipment), an option for Show Completed which causes only construction elements having all required variables defined to be shown, and an option for Show User Completed which causes only construction elements having all required variables defined which have been confirmed by the user to be shown. For duct and pipe fittings, options are also provided to filter by fitting type and/or system type.

For duct fittings, the system type may be selected from the group consisting of any one or more of S/A or SA (Supply Air), E/A or EA (Exhaust Air), R/A or RA (Return Air), G/A or GA (General Air), V/A or VA (Vent Air), W/E or WE (Washroom Exhaust), T/R or TR (Transfer), GEA (General Exhaust Air) and O/A or OA (Outside Air) in some examples.

For pipe fittings, for water, the system type may be selected from the group consisting of any two or more of Domestic Cold Water (DCW), Domestic Hot Water (DHW), Domestic Hot Water Return (DHR), Cold Soft Water (CSW), Heat Trace Hot Water (HT), Non-Potable Water (NPW), Deionized Water (DI), Reverse Osmosis Water (RO), Pure Water (PW), Process Cold Water (PCW), Process Hot Water (PHW), Process Hot Water Return (PHR), Lab Hot Water (LHR), Trap Filler Line (TF), Tempered Water (TW), Sanitation (SAN), Subsoil Drain (SD), Storm(S), Overflow Drain (OD), Force Main (FM), Clearwater Waste (CWW), Indirect Waste (IW), Grease Waste (GW), Corrosion Resistant Waste (CRW), Storm Sewer (STM), Pump Discharge (PD), Fire Main (F), Cold Water (CW), Hot Water (HW), Hot Water Supply (HTS), Hot Water Return (HWR), Acid Vent (AV), Oil Vent (OV), Oil Waste (OW), Drain Tile (DT), Storm Drainage (DS), and Storm Drainage Over Flow (ODS).

For pipe fittings, for gases, the system type may be selected from the group consisting of any two or more of Aragon (AR), Compressed Air (CA), Carbon Dioxide (CO2), Hydrogen (H2), Laboratory Compressed Air (LA), Liquid Nitrogen (LN2), Laboratory Vacuum (LVAC), Medical Compressed Air (MA), Medical Vacuum (MV), Natural Gas (NG), Nitrogen (N2), Nitrous Oxide (N2O), Oxygen (O2), Waste Anesthetic Gas Disposal (WAGD), and Waste Gas Evacuation (WGE).

For pipe fittings, for venting, the system type may be selected from the group consisting of any two or more of Vent (V), Clearwater Vent (CWV) and Corrosion Resistant Vent (CRV).

The filter options for fitting type and/or system type causing only fittings for matching duct or pipe fittings to be displayed. The visualization of the analyzed construction engineering drawings contains a lot of complex technical information which can be difficult to discern, even for knowledgeable and skilled professionals. The filtering options of the VUI simplify the displayed content of the VUI by causing the displayed content to be limited to matching construction elements, thereby facilitating user review and editing.

The Review Element window 1810 displays detected duct fittings, pipe fittings, duct lengths, pipe lengths and equipment and their associated properties. For duct fittings, pipe fittings and equipment, the pre-designated symbol associated with the respective fitting or equipment is displayed along with other information, including a thumbnail image of a corresponding portion of the construction engineering drawing at which the respective construction element was detected. A thumbnail is provided for added fittings as well as detected fittings. This allows the user to perform a visual comparison of the pre-designated symbol and the in-drawing symbol, and perform a correction of any error in recognition.

Referring to now FIG. 9, a method 1900 for training a neural network, such as the CRNN 340, or possibly the system 300, in accordance with one example embodiment of the present disclosure will be described. At least parts of the method 1900 are carried out by software executed by a processor 102. The method 1900 is typically performed offline.

At step 1902, system generated data (such as system sizes, types, equipment tags and the like) is collected in response to use of the system 300 to analyze engineering drawings in the ordinary course. The use may by AI/ML trainers, by paying users/customers, or automated/training uses by the system 300 itself, or other uses. The system generated data is data generated by the system 300 or elements thereof, i.e. predictions of the system 300. The system generated data is stored in memory in a training dataset for subsequent training purposes.

At step 1904, user corrected data (such as system sizes, types, equipment tags and the like) is collected in response to use of the system 300 to analyze engineering drawings. The user corrected data comprises corrections of system generated data made by users, i.e. corrections of the predictions of the system 300. The user corrected data is stored in memory in the training dataset for subsequent training purposes. Within the training data set, each user corrected data entry is associated with a corresponding system generated data entry which it corrects, forming a data pair. The pairs of user corrected data entries and system generated data entries may be stored as a pair or tuple in the dataset and/or linking information that associates or correlates the user corrected data entries and system generated data entries of the respective pairs may be stored in the training dataset.

At step 1906, one or more triggers for initiating a training cycle is monitored. The one or more triggers may comprise the expiry of a predetermined duration from a previous training cycle, a predetermined amount of user corrected data from a previous training cycle, of a combination thereof.

At step 1908, a data pair is selected from the training dataset comprising a system generated data entry and a user corrected data entry for the system generated data entry.

At step 1910, a training error is calculated based on a difference between the selected system generated data entry and the selected user corrected data entry for the system generated data entry. The nature of the training depends on the data type, e.g. system size, type, or equipment tag.

At step 1912, the system 300 is trained/retained by updating one or more parameters (e.g., weights) of a neural network of the system 300 based on the training error. In some examples, the one or more parameters of the neural network of the system 300 may be updated by through back propagation. In some examples, the one or more parameters of the neural network of the system 300 may be updated to minimize the training error through back propagation. For example, the parameters of the neural network may be updated to minimize a mean square error (MSE) between the system generated data entries and user corrected data entries.

At step 1914, it is determined whether any more tuples in the training dataset have not been analyzed. When more tuples requiring processing remain, the operations return to step 1908 at which a new data pair is selected and processed.

When no tuples requiring processing remain, the training cycle ends and the training dataset is cleared or empty. In some examples, the training dataset may be added to a historical training dataset before being cleared/emptied. The historical training dataset is a chronological log of training data used to train the system 300. A log of the historical training dataset may be maintained in which one or more of a date, time and training cycle ID of the respective training cycle associated with each entry of the historical training dataset is stored. The log may be provided by a data structure of the historical training dataset or may be separate therefrom. A counter and/or countdown timer associated with any trigger for initiating the training cycle is also reset.

### General

The foregoing description refers to a number of documents, datasets, programs/applications and code, the content of which is incorporated herein by reference in their entirety.

The coding of software for carrying out the above-described methods described is within the scope of a person of ordinary skill in the art having regard to the present disclosure. Machine-readable code executable by one or more processors of one or more respective devices to perform the above-described method may be stored in a machine-readable medium such as the memory of the data manager. The terms “software” and “firmware” are interchangeable within the present disclosure and comprise any computer program stored in memory for execution by a processor, comprising Random Access Memory (RAM) memory, Read Only Memory (ROM) memory, EPROM memory, electrically EPROM (EEPROM) memory, and non-volatile RAM (NVRAM) memory. The above memory types are examples only and are thus not limiting as to the types of memory usable for storage of a computer program.

All values and sub-ranges within disclosed ranges are also disclosed. Also, although the systems, devices and processes disclosed and shown herein may comprise a specific plurality of elements, the systems, devices and assemblies may be modified to comprise additional or fewer of such elements. Although several example embodiments are described herein, modifications, adaptations, and other implementations are possible. For example, substitutions, additions, or modifications may be made to the elements illustrated in the drawings, and the example methods described herein may be modified by substituting, reordering, or adding steps to the disclosed methods.

Features from one or more of the above-described embodiments may be selected to create alternate embodiments comprised of a subcombination of features which may not be explicitly described above. In addition, features from one or more of the above-described embodiments may be selected and combined to create alternate embodiments comprised of a combination of features which may not be explicitly described above. Features suitable for such combinations and subcombinations would be readily apparent to persons skilled in the art upon review of the present disclosure as a whole.

In addition, numerous specific details are set forth to provide a thorough understanding of the example embodiments described herein. It will, however, be understood by those of ordinary skill in the art that the example embodiments described herein may be practiced without these specific details. Furthermore, well-known methods, procedures, and elements have not been described in detail so as not to obscure the example embodiments described herein. The subject matter described herein and in the recited claims intends to cover and embrace all suitable changes in technology.

Although the present disclosure is described at least in part in terms of methods, a person of ordinary skill in the art will understand that the present disclosure is also directed to the various elements for performing at least some of the aspects and features of the described methods, be it by way of hardware, software or a combination thereof. Accordingly, the technical solution of the present disclosure may be embodied in a non-volatile or non-transitory machine-readable medium (e.g., optical disk, flash memory, etc.) having stored thereon executable instructions tangibly stored thereon that enable a processing device to execute examples of the methods disclosed herein.

The term “database” may refer to either a body of data, a relational database management system (RDBMS), or to both. As used herein, a database may comprise any collection of data comprising hierarchical databases, relational databases, flat file databases, object-relational databases, object-oriented databases, and any other structured collection of records or data that is stored in a computer system. The above examples are example only, and thus are not intended to limit in any way the definition and/or meaning of the terms “processor” or “database”.

The present disclosure may be embodied in other specific forms without departing from the subject matter of the claims. The described example embodiments are to be considered in all respects as being only illustrative and not restrictive. The present disclosure intends to cover and embrace all suitable changes in technology. The scope of the present disclosure is, therefore, described by the appended claims rather than by the foregoing description. The scope of the claims should not be limited by the embodiments set forth in the examples but should be given the broadest interpretation consistent with the description as a whole.

1. A method performed by a deep neural network (DNN)-based system for detecting and recognizing construction elements in construction engineering drawings, wherein the construction elements one or a combination of heating, ventilation, and air conditioning (HVAC) elements, plumbing elements, and equipment, the method comprising the steps of:
receiving, by the DNN-based system, a construction engineering drawing from a user computing device via a communication network;
performing, by a first neural network of the DNN-based system, object detection and recognition to detect and recognize ducts, pipe fittings and duct fittings in a construction engineering drawing, the first neural network outputting a unique object identifier (ID), construction element type and bounding box coordinates for each detected duct, duct fitting, pipe fitting and equipment symbol instance, each detected duct fitting and pipe fitting instance also being associated with an item type, each equipment symbol instance being associated with an equipment tag;
performing, by a second neural network of the DNN-based system, text detection to detect text in the construction engineering drawing, the second neural network outputting bounding box coordinates for each detected text instance;
performing, by a third neural network of the DNN-based system, text recognition upon each detected text instance to recognize the detected text contained therein, the third neural network outputting a recognized text string and bounding box coordinates for each detected text instance;
performing, by the DNN-based system, pixel tracing of the construction engineering drawing to detect pipes using the bounding box for each detected text instance as a reference point, the pixel tracing outputting a unique object ID, construction element type and pipe coordinates for each detected pipe instance;
filtering, by the DNN-based system, the recognized text in accordance with a predetermined set of rules to output a subset of construction element properties from the recognized text, wherein the predetermined set of rules applied depend on a construction element type associated with the recognized text, wherein the construction element properties comprises one or more of a system type, size and equipment tag;
generating, by the DNN-based system, a list of construction elements for all detected construction element instances, each construction element instance being one of a duct, duct fitting, pipe, pipe fitting or equipment instance, wherein each construction element instance in the list of construction elements defines construction element properties comprising a construction element instance type and one or more a system type, an item type, size, length, and equipment tag in dependence on the construction element instance type; and
instructing the user computing device to provide, on a display of the user computing device, an interactive visualization of the construction engineering drawing annotated within a visual user interface displayed on the display of the user computing device, wherein the annotated construction engineering drawing comprises an editable visual interface element for each detected construction element instance in the list of construction elements.

2. The method of claim 1, further comprising:
performing, by the first neural network of the DNN-based system, object detection and recognition to detect and recognize equipment symbols for equipment tags; and
associating the detected and recognized equipment symbols with recognized text output from the third neural network of the DNN-based system, wherein the recognized text associated with the detected and recognized equipment symbols is determined to be an equipment tag;
wherein the filtering applies predetermined rules for equipment tags on the recognized text associated with the detected shape or symbol to identify an equipment tag from the recognized text.

3. The method of claim 1, further comprising:
performing an action comprising one or more of:
obtaining and providing a costing of the list of construction elements to the user computing device via the communication network; or
outputting the costing of the list of construction elements to the user computing device via the communication network.

4. The method of claim 3, wherein the costing of the list of construction elements is provided by within the visual user interface provided on the display of the user computing device.

5. The method of claim 1, wherein the list of construction elements is provided by a quantity takeoff.

6. The method of claim 1, further comprising:
generating a quantity takeoff from the list of construction elements, wherein the quantity takeoff comprises the following information or counts: (i) length of duct, broken out by size (diameter and height/width), and system type; (ii) length of pipe, broken out by diameter and system type; (iii) quantity of pipe fittings by type, size (diameter and height/width), and system type; and (iv) quantity of duct fittings by type, size (diameter and height/width), and system type.

7. The method of claim 1, further comprising:
generating the annotated construction engineering drawing based on the construction engineering drawing and the list of construction elements; and
wherein the instructing comprises sending, via the communication network, the annotated construction engineering drawing to the user computing device with instructions which, when executed by the user computing device, cause the interactive visualization of the annotated construction engineering to be displayed on the display thereof.

8. The method of claim 1, wherein the outputting comprises communicating the list of construction elements to a cost module via an application programming interface (API), wherein the cost estimate is generated by the cost module which returns the cost estimation via the API.

9. The method of claim 1, further comprising:
generating a cost estimation comprising a cost of materials for each detected duct, pipe or fitting instance along with a total cost based on an individual cost of each duct, pipe or fitting instance based on the list of construction elements, wherein the cost estimation preferably further comprises a cost of materials for each detected equipment instance.

10. The method of claim 9, further comprising:
instructing the user computing device to provide the cost estimation to the user computing device, wherein the instructing comprises sending, via the communication network, the cost estimation to the user computing device with instructions which, when executed by the user computing device, cause the cost estimation to be displayed on the display thereof.

11. The method of claim 1, wherein the interactive visualization represents each detected construction element as a dynamic, selectable visual interface element having changeable properties.

12. The method of claim 1, further comprising:
changing parameters of recognized construction elements, adding construction elements and removing construction elements in response to corresponding user input via the visual user interface provided on the display of the user computing device, wherein changes, additions and removals automatically update the list of construction elements, corresponding data records and the visualization of the construction engineering drawing in real-time.

13. The method of claim 12, wherein the construction element type associated with the recognized text is determined by:
matching the bounding box coordinates of the recognized text with the bounding box coordinates or pipe coordinates of a matching detected duct, duct fitting, pipe, pipe fitting or equipment instance; and
determining the construction element type associated with the matching detected duct, duct fitting, pipe, pipe fitting or equipment instance.

14. The method of claim 13, wherein the bounding box coordinates of the recognized text are determined to match the bounding box coordinates or pipe coordinates of a detected duct, duct fitting, pipe, pipe fitting or equipment instance when the coordinates are within a threshold distance from each other.

15. The method of claim 1, wherein the interactive visualization provides real-time interactions between the user computing device and the DNN-based system.

16. The method of claim 1, wherein each construction element is defined by a data record stored in a database managed by the system, each data record in the database comprising a corresponding object identifier (ID) which uniquely identifies the respective construction element within the construction engineering drawing and information about the respective construction element including the construction element type, construction element properties and a location within the construction engineering drawing at which the construction element is located.

17. The method of claim 16, wherein a data record is generated and stored for each construction element detected by the DNN-based system or added by a user.

18. The method of claim 1, wherein the first neural network is a convolutional network (CNN), the second neural network is a Character-Region Awareness for Text detection (CRAFT) CNN, and the third neural network is a convolutional recurrent neural network (CRNN).

19. The method of claim 1, further comprising:
calculating a training error based on a difference between a system generated data entry and a user corrected data entry for the system generated data entry; and
training the system by updating one or more parameters of a neural network of the system based on the training error.

20. A deep neural network (DNN)-based system for detecting and recognizing construction elements in construction engineering drawings, wherein the construction elements one or a combination of heating, ventilation, and air conditioning (HVAC) elements, plumbing elements, and equipment, the DNN-based system comprising:
one or more processors;
one or more memories; and
a communication subsystem;
wherein the one or more memories have tangibly stored thereon executable instructions for execution by the one or more processors, wherein the executable instructions, in response to execution by the one or more processors, cause the computing device to:
receive a construction engineering drawing from a user computing device via a communication network via the communication subsystem;
perform, by a first neural network, object detection and recognition to detect and recognize ducts, pipe fittings and duct fittings in a construction engineering drawing, the first neural network outputting a unique object identifier (ID), construction element type and bounding box coordinates for each detected duct, duct fitting, pipe fitting and equipment symbol instance, each detected duct fitting and pipe fitting instance also being associated with an item type, each equipment symbol instance being associated with an equipment tag;
perform, by a second neural network, text detection to detect text in the construction engineering drawing, the second neural network outputting bounding box coordinates for each detected text instance;
perform, by a third neural network, text recognition upon each detected text instance to recognize the detected text contained therein, the third neural network outputting a recognized text string and bounding box coordinates for each detected text instance;
perform pixel tracing of the construction engineering drawing to detect pipes using the bounding box for each detected text instance as a reference point, the pixel tracing outputting a unique object ID, construction element type and pipe coordinates for each detected pipe instance;
filter the recognized text in accordance with a predetermined set of rules to output a subset of construction element properties from the recognized text, wherein the predetermined set of rules applied depend on a construction element type associated with the recognized text, wherein the construction element properties comprises one or more of a system type, size and equipment tag;
generate a list of construction elements for all detected construction element instances, each construction element instance being one of a duct, duct fitting, pipe, pipe fitting or equipment instance, wherein each construction element instance in the list of construction elements defines construction element properties comprising a construction element instance type and one or more a system type, an item type, size, length, and equipment tag in dependence on the construction element instance type; and
instruct the user computing device to provide, on a display of the user computing device, an interactive visualization of the construction engineering drawing annotated within a visual user interface displayed on the display of the user computing device, wherein the annotated construction engineering drawing comprises an editable visual interface element for each detected construction element instance in the list of construction elements.
